(19) United States
(12) Patent Application Publication
(10) Pub. No.: US 2025/0069972 A1
(43) Pub. Date: Feb. 27, 2025

(54) SEMICONDUCTOR PACKAGE

(71) Applicant: SAMSUNG ELECTRONICS CO., LTD., Suwon-si (KR)

(72) Inventors: Haseob Seong, Suwon-si (KR); Seungduk Baek, Suwon-si (KR); Aenee Jang, Suwon-si (KR)

(73) Assignee: SAMSUNG ELECTRONICS CO., LTD., Suwon-si (KR)

(21) Appl. No.: 18/658,652

(22) Filed: May 8, 2024

(30) Foreign Application Priority Data
Aug. 21, 2023 (KR) 10-2023-0109125

(51) Int. Cl. H01L 23/31; H01L 23/00; H01L 23/48; H01L 25/065

(52) U.S. Cl. CPC H01L 23/3107; H01L 23/481; H01L 24/08; H01L 25/0657; H01L 2224/08145

(57) ABSTRACT

Provided is a semiconductor package including a first semiconductor chip including a first semiconductor substrate having an active surface and an inactive surface opposite to each other, a plurality of second semiconductor chips each including a second semiconductor substrate having an active surface and an inactive surface opposite to each other, and a package molding layer including a bottom molding portion on a portion of an upper surface of the first semiconductor chip, which is exposed by the lowermost second semiconductor chip, and a side molding portion on side walls of the plurality of second semiconductor chips, wherein the side molding portion of the package molding layer extends in a vertical direction from an edge of an upper surface of the bottom molding portion of the package molding layer.

### CROSS-REFERENCE TO RELATED APPLICATION

This application claims priority to Korean Patent Application No. 10-2023-0109125, filed on Aug. 21, 2023, in the Korean Intellectual Property Office, the disclosure of which is incorporated by reference herein in its entirety.

### BACKGROUND

Embodiments of the present disclosure relate to a semiconductor package, and more particularly, to a semiconductor package including two dies directly stacked on each other through wafer-to-wafer bonding.

Electronic apparatuses are becoming more compact and lightweight according to the rapid development of the electronic industry and users' demand. As the electronic apparatuses become smaller and lighter, semiconductor packages used therein are also becoming smaller and lighter. In addition, high integration and high speed are required for the semiconductor packages. In response to the demands for the high integration and high speed of semiconductor packages, semiconductor packages including stacked semiconductor chips have been developed.

### SUMMARY

One or more embodiments provide a semiconductor package including stacked semiconductor chips and having improved structural reliability.

According to an aspect of an embodiment, there is provided a semiconductor package including a first semiconductor chip including a first semiconductor substrate having an active surface and an inactive surface opposite to each other and a plurality of first through-electrodes penetrating the first semiconductor chip, a plurality of second semiconductor chips each including a second semiconductor substrate having an active surface and an inactive surface opposite to each other and a plurality of second through-electrodes penetrating the plurality of second semiconductor chips, respectively, the plurality of second semiconductor chips being on the first semiconductor chip, the active surfaces of the plurality of second semiconductor substrates facing the inactive surface of the first semiconductor substrate, and the plurality of second semiconductor chips including a lowermost second semiconductor chip and an uppermost second semiconductor chip, a plurality of bonding pads between the first semiconductor chip and the lowermost second semiconductor chip and between the second semiconductor chips among the plurality of second semiconductor chips adjacent to each other, the plurality of bonding pads electrically connecting the plurality of first through-electrodes and the plurality of second through-electrodes to each other, a plurality of bonding insulating layers respectively between the first semiconductor chip and the lowermost second semiconductor chip and between the second semiconductor chips among the plurality of second semiconductor chips adjacent to each other, the plurality of bonding insulating layers being adjacent to the plurality of bonding pads, and a package molding layer including a bottom molding portion on a portion of an upper surface of the first semiconductor chip exposed by the lowermost second semiconductor chip, and a side molding portion on side walls of the plurality of second semiconductor chips, wherein the side molding portion included in the package molding layer extends in a vertical direction from an edge of an upper surface of the bottom molding portion included in the package molding layer.

According to another aspect of an embodiment, there is provided a semiconductor package including a first semiconductor chip including a first semiconductor substrate having an active surface and an inactive surface opposite to each other and a plurality of first through-electrodes penetrating the first semiconductor chip, a plurality of second semiconductor chips each including a second semiconductor substrate having an active surface and an inactive surface opposite to each other and a plurality of second through-electrodes penetrating the plurality of second semiconductor chips, respectively, the plurality of second semiconductor chips being on the first semiconductor chip, the active surfaces of the plurality of second semiconductor substrates facing the inactive surface of the first semiconductor substrate, and the plurality of second semiconductor chips including a lowermost second semiconductor chip and an uppermost second semiconductor chip, a plurality of bonding pads between the first semiconductor chip and the lowermost second semiconductor chip and between the second semiconductor chips among the plurality of second semiconductor chips adjacent to each other, the plurality of bonding pads electrically connecting the plurality of first through-electrodes and the plurality of second through-electrodes to each other, a plurality of bonding insulating layers respectively between the first semiconductor chip and the lowermost second semiconductor chip and between the second semiconductor chips among the plurality of second semiconductor chips adjacent to each other, the plurality of bonding insulating layers being adjacent to the plurality of bonding pads, a lower dummy support substrate on the uppermost second semiconductor chip, a cover layer including a top cover portion on an upper surface of the lower dummy support substrate and a side cover portion extending from the top cover portion and horizontally spaced apart from the lower dummy support substrate and the plurality of second semiconductor chips, and a package molding layer on a portion of an upper surface of the first semiconductor chip exposed by the lowermost second semiconductor chip, and being between the first semiconductor chip and the cover layer.

According to another aspect of an embodiment, there is provided a semiconductor package including a first semiconductor chip including a first semiconductor substrate having an active surface and an inactive surface opposite to each other and a plurality of first through-electrodes penetrating the first semiconductor chip, a plurality of second semiconductor chips each including a second semiconductor substrate having an active surface and an inactive surface opposite to each other and a plurality of second through-electrodes penetrating the plurality of second semiconductor chips, respectively, the plurality of second semiconductor chips being on the first semiconductor chip, the active surfaces of the plurality of second semiconductor substrates facing the inactive surface of the first semiconductor substrate, and the plurality of second semiconductor chips including a lowermost second semiconductor chip and an uppermost second semiconductor chip, a plurality of bonding pads between the first semiconductor chip and the lowermost second semiconductor chip and between the second semiconductor chips among the plurality of second semiconductor chips adjacent to each other, the plurality of bonding pads electrically connecting the plurality of first through-electrodes and the plurality of second through-electrodes to each other, a plurality of bonding insulating layers respectively between the first semiconductor chip and the lowermost second semiconductor chip and between the second semiconductor chips among the plurality of second semiconductor chips adjacent to each other, the plurality of bonding insulating layers being adjacent to the plurality of bonding pads, a package molding layer including a bottom molding portion on a portion of an upper surface of the first semiconductor chip, exposed by the lowermost second semiconductor chip, and a side molding portion on side walls of the plurality of second semiconductor chips, a lower dummy support substrate on the uppermost second semiconductor chip, a cover layer on the lower dummy support substrate, and an upper dummy support substrate on the cover layer, wherein the side molding portion included in the package molding layer extends in a vertical direction from an edge of an upper surface of the bottom molding portion included in the package molding layer, and a width of the side molding portion of the package molding layer is less than a width of the bottom molding portion of the package molding layer in a horizontal direction.

### BRIEF DESCRIPTION OF DRAWINGS

Embodiments will be more clearly understood from the following detailed description taken in conjunction with the accompanying drawings in which:

FIG. 1 is a cross-sectional view illustrating a semiconductor package according to embodiments;

FIGS. 2A, 2B, and 2C are layouts illustrating semiconductor packages according to embodiments;

FIG. 3 is a cross-sectional view illustrating a semiconductor package according to embodiments;

FIGS. 4A, 4B, and 4C are layouts illustrating semiconductor packages according to embodiments;

FIG. 5 is a cross-sectional view illustrating a semiconductor package according to embodiments;

FIGS. 6A, 6B, 6C, and 6D are layouts illustrating semiconductor packages according to embodiments; and

FIGS. 7, 8, 9, 10, 11, 12, 13, 14, 15A, 15B, 16A, 16B, 17A, and 17B are cross-sectional views illustrated in process order to describe a method of manufacturing a semiconductor package, according to embodiments.

### DETAILED DESCRIPTION

Hereinafter, embodiments are described in detail with reference to the accompanying drawings. The same reference numerals are used for the same elements in the drawings, and redundant descriptions thereof are omitted.

Embodiments described herein are example embodiments, and thus, the disclosure is not limited thereto.

It will be understood that, although the terms first, second, third, fourth, etc. may be used herein to describe various elements, components, regions, layers and/or sections (collectively “elements”), these elements should not be limited by these terms. These terms are only used to distinguish one element from another element. Thus, a first element described in this description section may be termed a second element or vice versa in the claim section without departing from the teachings of the disclosure.

It will be understood that when an element or layer is referred to as being “over,” “above,” “on,” “below,” “under,” “beneath,” “connected to” or “coupled to” another element or layer, it can be directly over, above, on, below, under, beneath, connected or coupled to the other element or layer or intervening elements or layers may be present. In contrast, when an element is referred to as being “directly over,” “directly above,” “directly on,” “directly below,” “directly under,” “directly beneath,” “directly connected to” or “directly coupled to” another element or layer, there are no intervening elements or layers present.

Further, spatially relative terms, such as “beneath,” “below,” “lower,” “above,” “upper,” and the like, may be used herein for ease of description to describe one element's or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the term “below” can encompass both an orientation of above and below. The device may be otherwise oriented (rotated 90 degrees or at other orientations), and the spatially relative descriptors used herein may be interpreted accordingly.

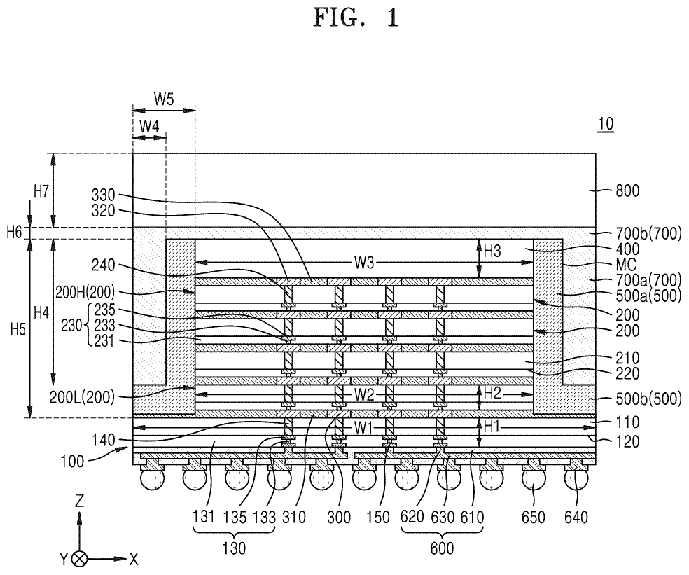

FIG. 1 is a cross-sectional view illustrating a semiconductor package 10 according to embodiments.

Referring to FIG. 1, the semiconductor package 10 includes a first semiconductor chip 100 and a plurality of second semiconductor chips 200. Although the semiconductor package 10 shown in FIG. 1 includes four second semiconductor chips 200, embodiments are not limited thereto. For example, the semiconductor package 10 may include two or more second semiconductor chips 200. In embodiments, the number of second semiconductor chips 200 included in the semiconductor package 10 may be a multiple of 4.

The plurality of second semiconductor chips 200 may be sequentially stacked on the first semiconductor chip 100. As used herein, for convenience of description, a second semiconductor chip 200, which is located at the bottom among the plurality of second semiconductor chips 200 and disposed on the first semiconductor chip 100, may be defined as a lowermost second semiconductor chip 200L. Also, a second semiconductor chip 200, which is located at the top among the plurality of second semiconductor chips 200, may be defined as an uppermost second semiconductor chip 200H.

As used herein, a direction in which the first semiconductor chip 100 extends may be defined as a first horizontal direction X, a direction which intersects with the first horizontal direction X and in which the first semiconductor chip 100 extends may be defined as a second horizontal direction Y, and a direction which is perpendicular to the upper surface the first semiconductor chip 100 may be defined as a vertical direction Z. Also, the first horizontal direction X or the second horizontal direction Y may be referred to as a horizontal direction X or Y.

The first semiconductor chip 100 may include a first semiconductor substrate 110 having an active surface 120 and an inactive surface opposing each other, a first individual device disposed on the active surface 120 of the first semiconductor substrate 110, a first wiring structure 130 disposed on the active surface 120 of the first semiconductor substrate 110, and a plurality of first through-electrodes 140 connected to the first wiring structure 130 and penetrating through the first semiconductor substrate 110. The first wiring structure 130 may include a first wiring layer 131, a first wiring via 133, and a first wiring pattern 135.

The first semiconductor chip 100 may further include a plurality of chip pads 150 which are arranged on the lower surface of the first semiconductor chip 100 and electrically connected to the first wiring structure 130. The plurality of chip pads 150 may be electrically connected to the first wiring via 133 and/or the first wiring pattern 135 or may be electrically connected to the first individual device through the first wiring via 133 and/or the first wiring pattern 135.

In the semiconductor package 10, the first semiconductor chip 100 may be arranged such that the active surface 120 of the first semiconductor substrate 110 faces the bottom and the inactive surface of the first semiconductor substrate 110 faces the top.

Each of the second semiconductor chips 200 may include a second semiconductor substrate 210 having an active surface 220 and an inactive surface opposing each other, a second individual device disposed on the active surface 220 of the second semiconductor substrate 210, a second wiring structure 230 disposed on the active surface 220 of the second semiconductor substrate 210, and a plurality of second through-electrodes 240 connected to the second wiring structure 230 and penetrating through the second semiconductor substrate 210. The second wiring structure 230 may include a second wiring layer 231, a second wiring via 233, and a second wiring pattern 235.

The uppermost second semiconductor chip 200H among the plurality of second semiconductor chips 200 may include a plurality of support bonding pads 320 which are arranged on the upper surface of the uppermost second semiconductor chip 200H and electrically connected to the second wiring structure 230. The plurality of support bonding pads 320 may be electrically connected to the plurality of second through-electrodes 240 and may be electrically connected to the second wiring via 233 and/or the second wiring pattern 235 through the plurality of second through-electrodes 240.

In the semiconductor package 10, the second semiconductor chip 200 may be arranged such that the active surface 220 of the second semiconductor substrate 210 faces the bottom and the inactive surface of the second semiconductor substrate 210 faces the top. For example, the second semiconductor chip 200 may be arranged such that the active surface 220 of the second semiconductor substrate 210 faces the inactive surface of the first semiconductor chip 100.

The first semiconductor substrate 110 and the second semiconductor substrate 210 may include, for example, a semiconductor material, such as silicon (Si). Also, the first semiconductor substrate 110 and the second semiconductor substrate 210 may include a semiconductor material, such as germanium (Ge). The first semiconductor substrate 110 and the second semiconductor substrate 210 may include a conductive region, for example, a well doped with impurities. The first semiconductor substrate 110 and the second semiconductor substrate 210 may have various device isolation structures, such as a shallow trench isolation (STI) structure.

Each of the first individual device and the second individual device may include a plurality of various types of individual devices. The plurality of individual devices may include various microelectronic devices, for example, metal-oxide-semiconductor field effect transistors (MOSFET), such as complementary metal-oxide-semiconductor (CMOS) transistors, system large scale integration (LSI), image sensors, such as CMOS imaging sensors (CIS), micro-electro-mechanical systems (MEMS), active elements, passive elements, etc.

Each of the first individual device and the second individual device may further include a conductive wire or a conductive plug. Through the conductive wire or conductive plug, the plurality of individual devices included in the first individual device or the second individual device may be electrically connected to the conductive region of the first semiconductor substrate 110 or the second semiconductor substrate 210. The plurality of individual devices may be electrically separated from other neighboring individual devices by an insulating film.

The first semiconductor chip 100 or the second semiconductor chip 200 may include a memory semiconductor chip. In embodiments, the first semiconductor chip 100 may include a serial-parallel conversion circuit and may include a buffer chip for controlling the plurality of second semiconductor chips 200. Also, the plurality of second semiconductor chips 200 may include memory chips with memory cells. For example, the semiconductor package 10 including the first semiconductor chip 100 and the plurality of second semiconductor chips 200 may include high bandwidth memory (HBM). The first semiconductor chip 100 may be referred to as an HBM control die and each of the plurality of second semiconductor chips 200 may be referred to as a dynamic random access memory (DRAM) die.

The first wiring structure 130 may include a first wiring layer 131, a plurality of first wiring vias 133 penetrating through a portion of the first wiring layer 131, and a plurality of first wiring patterns 135 connected to the plurality of first wiring vias 133. In embodiments, the plurality of first wiring vias 133 and the plurality of first wiring patterns 135 may be at different levels in the vertical direction Z, and the first wiring structure 130 may have a multi-layer wiring structure.

The second wiring structure 230 may include a second wiring layer 231, a plurality of second wiring vias 233 penetrating through a portion of the second wiring layer 231, and a plurality of second wiring patterns 235 connected to the plurality of second wiring vias 233. In embodiments, the plurality of second wiring vias 233 and the plurality of second wiring patterns 235 may be at different levels in the vertical direction Z, and the second wiring structure 230 may have a multi-layer wiring structure.

When the first wiring structure 130 and the second wiring structure 230 have multi-layer wiring structures, the first wiring layer 131 and the second wiring layer 231 may have multi-layer structures which correspond to the multi-layer wiring structures of the first and second wiring structures 130 and 230 and in which a plurality of insulating layers are stacked.

In embodiments, the first wiring layer 131 and the second wiring layer 231 may include an insulating material. For example, the first wiring layer 131 and the second wiring layer 231 may include silicon oxide, silicon nitride, silicon oxynitride, an insulating material with lower permittivity than the silicon oxide, or a combination thereof. In embodiments, the first wiring layer 131 and the second wiring layer 231 may include a tetraethyl orthosilicate (TEOS) film or an ultralow K (ULK) film having an ultralow dielectric constant K of about 2.2 to about 2.4. The ULK film may include a silicon oxycarbide (SiOC) film or an SiCOH film.

In embodiments, the first wiring via 133, the first wiring pattern 135, the second wiring via 233, and the second wiring pattern 235 may include a conductive material. For example, the first wiring via 133, the first wiring pattern 135, the second wiring via 233, and the second wiring pattern 235 may include aluminum, copper, or tungsten. In embodiments, the first wiring via 133, the first wiring pattern 135, the second wiring via 233, and the second wiring pattern 235 may include a wiring barrier film and a wiring metal layer. The wiring barrier film may include metal, metal nitride, or alloy. The wiring metal layer may include one metal selected from among tungsten (W), aluminum (Al), titanium (Ti), tantalum (Ta), ruthenium (Ru), magnesium (Mn), and copper (Cu.)

In embodiments, each of the first through-electrodes 140 and the second through-electrodes 240 may be provided in the form of a through silicon via (TSV). The first through-electrodes 140 and the second through-electrodes 240 may include conductive plugs respectively penetrating through the first semiconductor substrate 110 and the second semiconductor substrate 210 and conductive barrier films surrounding and adjacent to the conductive plugs. Each of the conductive plugs may have a cylindrical shape and each of the conductive barrier films may have a cylinder shape surrounding and adjacent to a side wall of the conductive plug. A via insulating film may be located between the first through-electrode 140 and the first semiconductor substrate 110 and between the second through-electrode 240 and the second semiconductor substrate 210 and may be adjacent to and surround side walls of the first through-electrode 140 and the second through-electrode 240. The first through-electrode 140 and the second through-electrode 240 may have any one of a via-first structure, a via-middle structure, and a via-last structure.

The first semiconductor chip 100 and the plurality of second semiconductor chips 200 may be electrically connected through a plurality of bonding pads 300 to exchange signals and provide power and ground. The plurality of bonding pads 300 may be arranged between the first semiconductor chip 100 and the lowermost second semiconductor chip 200L and between the plurality of second semiconductor chips 200 that are in contact with each other. A bonding insulating layer 310 may be located between the first semiconductor chip 100 and the lowermost second semiconductor chip 200L and between the plurality of second semiconductor chips 200 that are in contact with each other and may be adjacent to and surround the plurality of bonding pads 300. The plurality of bonding pads 300 may be adjacent to and surrounded by the bonding insulating layer 310 in a plan view.

Each of the plurality of bonding pads 300 may be arranged between the second wiring via 233 and/or the second wiring pattern 235 of the second wiring structure 230 and the first through-electrode 140 and between the second wiring via 233 and/or the second wiring pattern 235 of the second wiring structure 230 and the second through-electrode 240. The plurality of bonding pads 300 may electrically connect the second wiring vias 233 and/or the second wiring patterns 235 of the second wiring structure 230 to the first through-electrodes 140 or the second through-electrodes 240. For example, the plurality of bonding pads 300 may electrically connect the plurality of first through-electrodes 140 and the plurality of second through-electrodes 240 to each other.

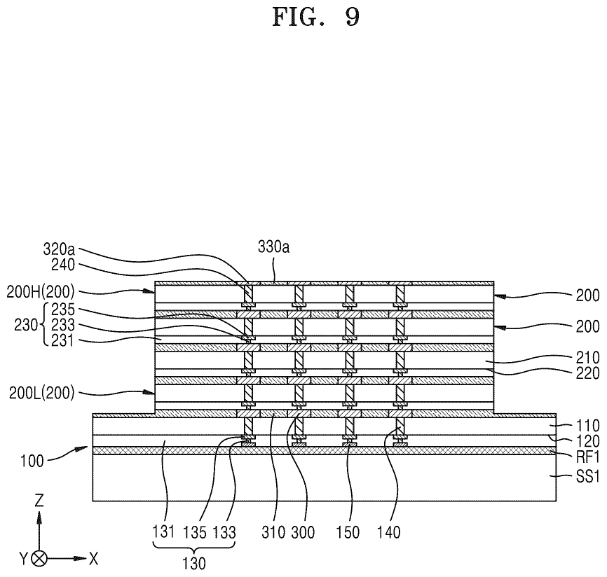

In embodiments, the plurality of bonding pads 300 may be formed by diffusion bonding of: respectively forming conductive material layers on facing surfaces of two adjacent chips among the first semiconductor chip 100 and the plurality of second semiconductor chips 200; expanding the conductive material layers using heat to bring the conductive material layers into contact with each other; and diffusing metal atoms in the conductive material layers so that the conductive material layers are integrated with each other. A method of forming the plurality of bonding pads 300 is described in detail in descriptions with reference to FIG. 9.

In embodiments, the bonding insulating layer 310 may be formed by diffusion bonding including respectively forming insulating material layers on facing surfaces of two adjacent chips among the first semiconductor chip 100 and the plurality of second semiconductor chips 200, expanding the insulating material layers using heat to bring the insulating material layers into contact with each other, and diffusing atoms in the insulating material layers so that the insulating material layers are integrated with each other. A method of forming the bonding insulating layer 310 is described in detail in descriptions with reference to FIG. 9.

A bonding insulating layer 310, which is located between the first semiconductor chip 100 and the lowermost second semiconductor chip 200L, among the plurality of bonding insulating layers 310 may be referred to as a lowermost bonding insulating layer 310. The lowermost bonding insulating layer 310 may include a portion overlapping the lowermost second semiconductor chip 200L in the vertical direction Z and a portion not overlapping the lowermost second semiconductor chip 200L in the vertical direction Z.

The height of the portion of the lowermost bonding insulating layer 310 in the vertical direction Z, which overlaps the lowermost second semiconductor chip 200L, may be greater than the height of the portion of the lowermost bonding insulating layer 310 in the vertical direction Z, which does not overlap the lowermost second semiconductor chip 200L. For example, the lowermost bonding insulating layer 310 may include a recess in the portion of the lowermost bonding insulating layer 310 which does not overlap the lowermost second semiconductor chip 200L. The upper surface of the lowermost bonding insulating layer 310 may protrude upward at the portion overlapping the lowermost second semiconductor chip 200L, due to the recess, compared to the portion not overlapping the lowermost second semiconductor chip 200L.

The lowermost bonding insulating layer 310 may cover a portion of the upper surface of the first semiconductor chip 100 which does not overlap the lowermost second semiconductor chip 200L. The lowermost bonding insulating layer 310 may cover the upper surface of the first semiconductor chip 100 that is not covered by the plurality of bonding pads 300, at the portion of the upper surface of the first semiconductor chip 100 that overlaps the lowermost second semiconductor chip 200L.

The other bonding insulating layers 310 other than the lowermost bonding insulating layer 310 among the plurality of bonding insulating layers 310 may cover portions of the upper and lower surfaces of the second semiconductor chips 200, which are not covered by the plurality of bonding pads 300.

A lower dummy support substrate 400 may be disposed on the uppermost second semiconductor chip 200H. The lower dummy support substrate 400 may include, for example, a semiconductor material, such as silicon (Si). In embodiments, the lower dummy support substrate 400 may include only the semiconductor material. For example, the lower dummy support substrate 400 may include a portion of a bare wafer.

The first semiconductor chip 100 may have a first width W1 in the first horizontal direction X and a first height H1 in the vertical direction Z. When the plurality of second semiconductor chips 200 has substantially the same width in the first horizontal direction X and substantially the same height in the vertical direction Z, each of the plurality of second semiconductor chips 200 may have a second width W2 in the first horizontal direction X and a second height H2 in the vertical direction Z. The lower dummy support substrate 400 may have a third width W3 in the first horizontal direction X and a third height H3 in the vertical direction Z.

In embodiments, the first width W1 of the first semiconductor chip 100 may be equal to or greater than the second width W2 of the second semiconductor chip 200 in the horizontal direction X. For example, the first width W1 may be about 11 millimeters and the second width W2 may be about 10 millimeters. In embodiments, the second width W2 of the second semiconductor chip 200 may be greater than or equal to the third width W3 of the lower dummy support substrate 400. For example, the second width W2 may be about 10 millimeters and the third width W3 may be about 9 millimeters. In embodiments, the first height H1 of the first semiconductor chip 100 may be greater than or equal to the second height H2 of the second semiconductor chip 200 in the vertical direction Z. For example, the first height H1 may be about 60 micrometers and the second height H2 may be about 40 micrometers. In embodiments, the first height H1 of the first semiconductor chip 100 may be less than the third height H3 of the lower dummy support substrate 400. For example, the first height H1 may be about 60 micrometers and the third height H3 may be about 200 micrometers.

The plurality of support bonding pads 320 may be arranged between the uppermost second semiconductor chip 200H and the lower dummy support substrate 400. A support bonding insulating layer 330 may be located between the uppermost second semiconductor chip 200H and the lower dummy support substrate 400 and may be adjacent to and surround the plurality of support bonding pads 320. The plurality of support bonding pads 320 may be adjacent to and surrounded by the support bonding insulating layer 330 in a plan view.

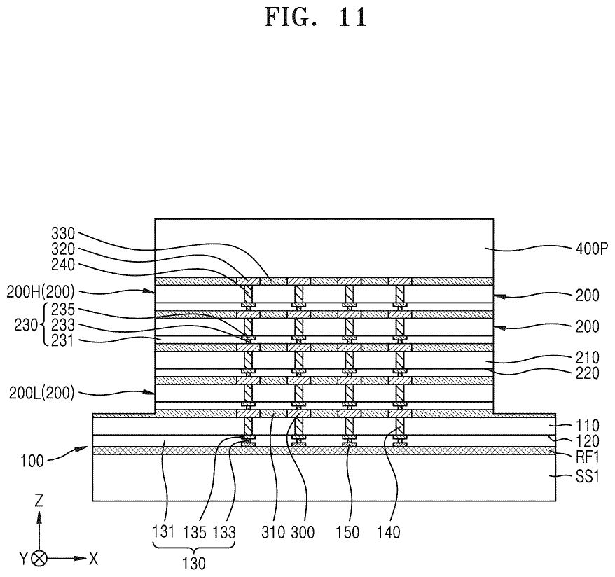

In embodiments, the plurality of support bonding pads 320 may be formed by diffusion bonding including respectively forming conductive material layers on the upper surface of the uppermost second semiconductor chip 200H and the lower surface of the lower dummy support substrate 400, which face each other, expanding the conductive material layers using heat to bring the conductive material layers into contact with each other, and diffusing metal atoms in the conductive material layers so that the conductive material layers are integrated with each other. A method of forming the plurality of support bonding pads 320 is described in detail in descriptions with reference to FIG. 11.

In embodiments, the support bonding insulating layer 330 may be formed by diffusion bonding including respectively forming insulating material layers on the upper surface of the uppermost second semiconductor chip 200H and the lower surface of the lower dummy support substrate 400, which face each other, expanding the insulating material layers using heat to bring the insulating material layers into contact with each other, and diffusing atoms in the insulating material layers so that the insulating material layers are integrated with each other. A method of forming the support bonding insulating layer 330 is described in detail in descriptions with reference to FIG. 11.

The support bonding insulating layer 330 may cover portions of the upper surface of the uppermost second semiconductor chip 200H and the lower surface of the lower dummy support substrate 400, which are not covered by the plurality of support bonding pads 320.

In embodiments, the plurality of bonding pads 300 and the plurality of support bonding pads 320 may include a material, such as copper (Cu), capable of diffusion bonding. In embodiments, the bonding insulating layer 310 and the support bonding insulating layer 330 may include any one of silicon oxide (SiO), silicon nitride (SiN), silicon carbon-nitride (SiCN), silicon carbon-oxide (SiCO), and a polymer material. The polymer material may include benzocyclobutene (BCB), polyimide (PI), polybenzoxazole (PBO), silicone, acrylate, or epoxy. For example, the bonding insulating layer 310 and the support bonding insulating layer 330 may include silicon oxide. In embodiments, the bonding insulating layer 310 and the support bonding insulating layer 330 may include the same material. The bonding insulating layer 310 and the support bonding insulating layer 330 may have a thickness of, for example, about 100 nanometers to about 1 micrometer.

The semiconductor package 10 may include a package molding layer 500 that covers the portion of the upper surface of the first semiconductor chip 100 which is not covered and exposed by the lowermost second semiconductor chip 200L. The package molding layer 500 may be adjacent to and surround side walls of the plurality of second semiconductor chips 200 and side walls of the lower dummy support substrate 400. The package molding layer 500 may include, for example, an epoxy mold compound (EMC).

The package molding layer 500 is shown as not covering the upper surface of the lower dummy support substrate 400, but embodiments are not limited thereto. The package molding layer 500 may extend to cover the upper surface of the lower dummy support substrate 400. The package molding layer 500 may include a bottom molding portion 500b covering a portion of the upper surface of the first semiconductor chip 100, which is not covered and exposed by the lowermost second semiconductor chip 200L, and a side molding portion 500a covering side walls of the plurality of second semiconductor chips 200 and side walls of the lower dummy support substrate 400. The side molding portion 500a and the bottom molding portion 500b may form a stepped structure. The side molding portion 500a may extend from the edge of the upper surface of the bottom molding portion 500b in the vertical direction Z and may extend to the side wall of the lower dummy support substrate 400. The side molding portion 500a may be in contact with the side walls of the plurality of second semiconductor chips 200 and the side walls of the lower dummy support substrate 400, and the bottom molding portion 500b may be in contact with the lowermost bonding insulating layer 310.

The side molding portion 500a may partially cover the upper surface of the bottom molding portion 500b. The width of the side molding portion 500a in the horizontal direction X or Y may be less than the width of the bottom molding portion 500b in the horizontal direction X or Y. For example, a width of the side molding portion 500a in the horizontal direction X or Y, which is obtained by subtracting W4 from W5 (i.e., W5−W4), may be less than a width W5 of the bottom molding portion 500b in the horizontal direction X or Y.

The package molding layer 500 may include a package molding cut MC. The side wall of the side molding portion 500a may be defined by the side wall of the package molding cut MC and the upper surface of the bottom molding portion 500b may be defined by the bottom of the package molding cut MC. The package molding cut MC may include a first molding cut facing the side walls of the plurality of second semiconductor chips 200 and a first side wall of the lower dummy support substrate 400 and a second molding cut facing a second side wall of the lower dummy support substrate 400 opposite to the first side wall.

The package molding cut MC may have a fourth width W4 in the first horizontal direction X and a fourth height H4 in the vertical direction Z. The package molding layer 500 may have a maximum fifth width W5 in the first horizontal direction X and a maximum fifth height H5 in the vertical direction Z. The fourth width W4 of the package molding cut MC may be less than the fifth width W5 of the package molding layer 500. The fourth height H4 of the package molding cut MC may be less than the fifth height H5 of the package molding layer 500. The fourth width W4 and fourth height H4 of the package molding cut MC may be adjusted by the width and height of a sawing blade, which is described below.

In embodiments, the semiconductor package 10 may further include a base redistribution layer 600 disposed on the lower surface of the first semiconductor chip 100. The base redistribution layer 600 may include a package redistribution insulating layer 610, a plurality of package redistribution vias 620, and a package redistribution line pattern 630.

In embodiments, a plurality of package redistribution insulating layers 610 may be stacked. The package redistribution insulating layer 610 may be formed from, for example, photo imageable dielectric (PID) or photosensitive polyimide (PSPI).

Each of the package redistribution vias 620 may pass through the package redistribution insulating layer 610 and be connected to the package redistribution line pattern 630. The package redistribution vias 620 may be adjacent to and surrounded by the package redistribution insulating layer 610 in a plan view. In embodiments, a plurality of package redistribution line patterns 630 may be stacked. The plurality of package redistribution line patterns 630 may each be disposed on the package redistribution insulating layer 610. In embodiments, the plurality of package redistribution vias 620 may be formed together with the package redistribution line pattern 630 and integrated into a single body.

The package redistribution via 620 and the package redistribution line pattern 630 may include, for example, metals, such as copper (Cu), aluminum (Al), tungsten (W), titanium (Ti), indium (In), molybdenum (Mo), manganese (Mn), cobalt (Co), tin (Sn), nickel (Ni), magnesium (Mg), rhenium (Re), beryllium (Be), gallium (Ga), ruthenium (Ru), or an alloy thereof. However, embodiments are not limited thereto. In some embodiments, the package redistribution via 620 and the package redistribution line pattern 630 may be formed by stacking a metal or a metal alloy on a seed layer including titanium, titanium nitride, or titanium tungsten.

The plurality of package redistribution vias 620 and the package redistribution line patterns 630 may be electrically connected to the plurality of chip pads 150. In embodiments, at least some of the plurality of package redistribution vias 620 may be in contact with the plurality of chip pads 150. For example, when the plurality of package redistribution insulating layers 610 are provided, a package redistribution via 620 penetrating through the uppermost package redistribution insulating layer 610 may be in contact with a chip pad 150.

In embodiments, the plurality of package redistribution vias 620 may each have a tapered shape extending from the bottom to the top with a decreasing horizontal width. For example, the horizontal width of each of the plurality of package redistribution vias 620 may increase in a direction away from the first semiconductor chip 100.

A package pad 640 may be disposed on the lower surface of the base redistribution layer 600. In embodiments, the package pad 640 may include the same material as the package redistribution line pattern 630. The package pad 640 may be provided in plurality, and the plurality of package pads 640 may be respectively in contact with a plurality of package connection terminals 650. For example, each of the package connection terminals 650 may include a solder ball or a bump.

In embodiments, the semiconductor package 10 may not include the base redistribution layer 600. For example, the plurality of package connection terminals 650 may be attached to the plurality of chip pads 150.

The semiconductor package 10 may further include a cover layer 700 disposed on the package molding layer 500. The cover layer 700 may cover the upper surface of the lower dummy support substrate 400 and the upper surface of the package molding layer 500 and may extend and fill the interior of the package molding cut MC.

The cover layer 700 may include a side cover portion 700a covering the side wall of the side molding portion 500a and the upper surface of the bottom molding portion 500b and a top cover portion 700b covering the upper surface of the lower dummy support substrate 400 and the upper surface of the side molding portion 500a. The side cover portion 700a may extend from the top cover portion 700b toward the bottom molding portion 500b and may extend to come into contact with the upper surface of the bottom molding portion 500b. The side cover portion 700a may overlap the lower dummy support substrate 400 or the plurality of second semiconductor chips 200 in the horizontal direction X or Y and may overlap the side molding portion 500a in the horizontal direction X or Y. The side cover portion 700a may be spaced apart from the lower dummy support substrate 400 or the plurality of second semiconductor chips 200 in the horizontal direction X or Y, and the side molding portion 500a may be located between the side cover portion 700a and the lower dummy support substrate 400 or the plurality of second semiconductor chips 200.

The cover layer 700 may be in contact with the side molding portion 500a through the side wall of the package molding cut MC and may be in contact with the bottom molding portion 500b through the bottom of the package molding cut MC. The side molding portion 500a may be in contact with the side cover portion 700a through the side wall of the package molding cut MC and the bottom molding portion 500b may be in contact with the side cover portion 700a through the bottom of the package molding cut MC. For example, the side wall of the side molding portion 500a may be in contact with the side wall of the side cover portion 700a and the upper surface of the bottom molding portion 500b may be in contact with the bottom of the side cover portion 700a.

The side cover portion 700a of the cover layer 700 may have the fourth width W4 in the first horizontal direction X. The fourth width W4 may be equal to the width of the package molding cut MC in the first horizontal direction X. The top cover portion 700b of the cover layer 700 may have a width substantially equal to the first width W1 of the first semiconductor chip 100 in the first horizontal direction X. Also, the side cover portion 700a of the cover layer 700 may have the fourth height H4 in the vertical direction Z. The fourth height H4 may be equal to the height of the package molding cut MC in the vertical direction Z. The top cover portion 700b of the cover layer 700 may have a sixth height H6 in the vertical direction Z. The sixth height H6 of the top cover portion 700b may be less than the first height H1 of the first semiconductor chip 100 or the second height H2 of each of the plurality of second semiconductor chips 200. For example, the sixth height H6 of the top cover portion 700b may be about 4470 angstroms.

In embodiments, the cover layer 700 may include an inorganic material, such as an oxide, but embodiments are not limited thereto. Any material may be included in the cover layer 700 as long as the material may fill a space between the lower dummy support substrate 400 and an upper dummy support substrate 800. For example, the cover layer 700 may include a metal, such as copper (Cu), and may be attached to the lower dummy support substrate 400 using a thermal interface material (TIM). In embodiments, the cover layer 700 may include a material different from that of the package molding layer 500.

The semiconductor package 10 may further include the upper dummy support substrate 800 on the cover layer 700. The upper dummy support substrate 800 may include, for example, a semiconductor material, such as silicon (Si). The upper dummy support substrate 800 may include only the semiconductor material. For example, the upper dummy support substrate 800 may include a portion of a bare wafer.

The upper dummy support substrate 800 may have a width substantially equal to the first width W1 of the first semiconductor chip 100 in the first horizontal direction X. The upper dummy support substrate 800 may have a seventh height H7 in the vertical direction Z. The seventh height H7 of the upper dummy support substrate 800 may be greater than the sum of the first height H1 of the first semiconductor chip 100 in the vertical direction Z and the second height H2 of any one of the plurality of second semiconductor chips 200 in the vertical direction Z. For example, the seventh height H7 of the upper dummy support substrate 800 may be about 110 micrometers to about 620 micrometers.

According to embodiments, the semiconductor package 10 may include a structure in which the first semiconductor chip 100 and the plurality of second semiconductor chips 200 are stacked on each other. The first semiconductor chip 100 and the second semiconductor chip 200 disposed on the first semiconductor chip 100 may be bonded to each other through diffusion bonding, for example, hybrid bonding of the plurality of bonding pads 300 and the bonding insulating layer 310. Similarly, the second semiconductor chips 200 adjacent to each other may be bonded to each other through diffusion bonding, for example, hybrid bonding of the plurality of bonding pads 300 and the bonding insulating layer 310.

According to embodiments, the semiconductor package 10 may include the package molding cut MC in the package molding layer 500. When the package molding layer 500 does not include the package molding cut MC, warpage of the package molding layer 500 may occur in a portion of the package molding layer 500 in which the coefficient of thermal expansion (CTE) is greater than a target CTE. According to embodiments, the package molding layer 500 includes a package molding cut MC, thereby preventing or reducing excessive thermal expansion and warpage of the package molding layer 500.

Also, since the first semiconductor chip 100, the plurality of second semiconductor chips 200, and the lower dummy support substrate 400 are coupled to each other through the hybrid bonding, the surface roughness of the first semiconductor chip 100 and the plurality of second semiconductor chips 200 may be accumulated up to the upper surface of the lower dummy support substrate 400. When the cover layer 700 is not located between the lower dummy support substrate 400 and the upper dummy support substrate 800, a structural defect may occur in which the upper dummy support substrate 800 may not be properly coupled to the lower dummy support substrate 400 due to the surface roughness of the upper surface of the lower dummy support substrate 400. According to embodiments, the cover layer 700 fills the space between the lower dummy support substrate 400 and the upper dummy support substrate 800. Accordingly, the surface roughness of the lower dummy support substrate 400 is compensated for by the cover layer 700, and thus, the upper dummy support substrate 800 may be properly coupled to the cover layer 700. Consequently, it is possible to improve the structural stability of the semiconductor package.

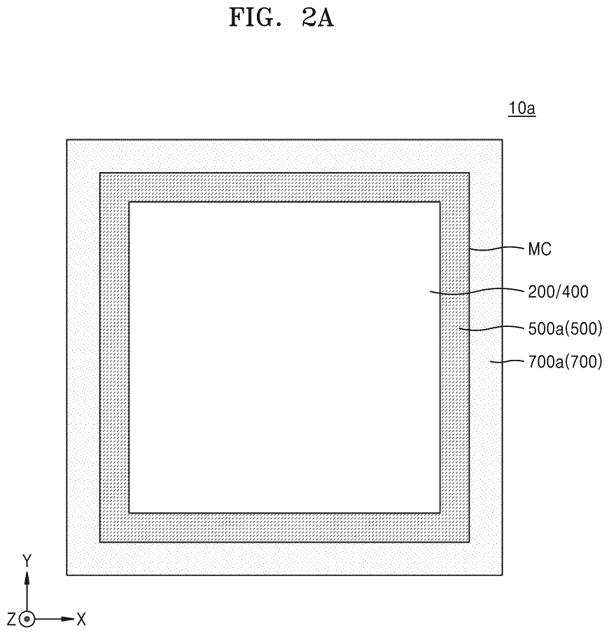

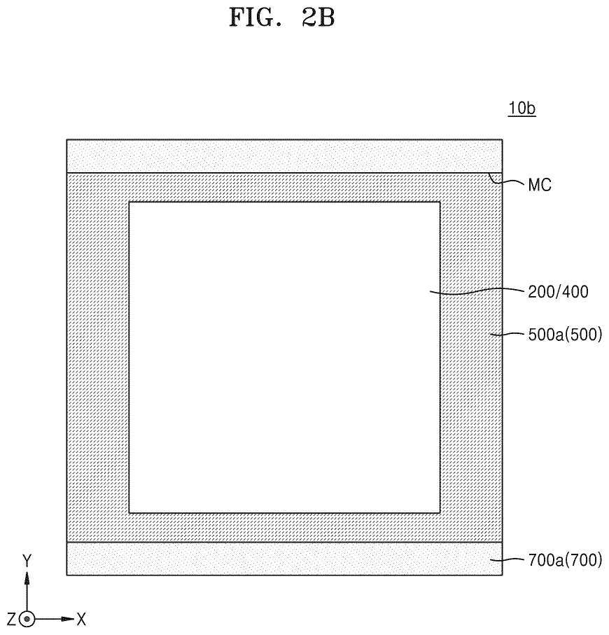

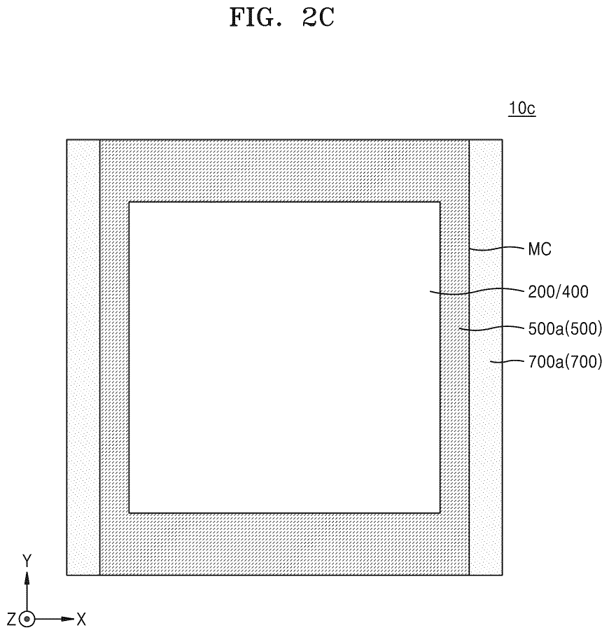

FIGS. 2A, 2B, and 2C are layouts illustrating semiconductor packages 10a, 10b, and 10c according to embodiments.

Referring to FIGS. 2A, 2B, and 2C, a package molding layer 500 may be adjacent to and surround a plurality of second semiconductor chips 200 and a lower dummy support substrate 400. The plurality of second semiconductor chips 200 and the lower dummy support substrate 400 may be adjacent to and surrounded by the package molding layer 500 in a plan view. Referring to FIG. 1 together, the side molding portion 500a of the package molding layer 500 may be adjacent to and surround the side walls of the plurality of second semiconductor chips 200 and the lower dummy support substrate 400. The bottom molding portion 500b of the package molding layer 500 may be provided below the side cover portion 700a of the cover layer 700 and may be adjacent to and surround portions of the side walls of the plurality of second semiconductor chips 200 and the lower dummy support substrate 400, which are not adjacent to and surrounded by the side molding portion 500a.

The package molding cut MC may include a plurality of first cuts extending in the first horizontal direction X or a plurality of second cuts extending in the second horizontal direction Y.

Referring to FIG. 2A, the package molding cut MC may include the plurality of first cuts and the plurality of second cuts. In the package molding cut MC, the plurality of first cuts may be spaced apart from each other in the second horizontal direction Y with the second semiconductor chip 200 and the lower dummy support substrate 400 therebetween and the plurality of second cuts may be spaced apart from each other in the first horizontal direction X with the second semiconductor chip 200 and the lower dummy support substrate 400 therebetween. At least one of the plurality of first cuts may be connected to at least one of the plurality of second cuts. However, the plurality of first cuts are not necessarily connected to the plurality of second cuts, and the plurality of first cuts and the plurality of second cuts may not be connected to each other.

The side cover portion 700a of the cover layer 700 may extend along the package molding cut MC. The side cover portion 700a may be adjacent to and surround the lower dummy support substrate 400 or the lower dummy support substrate 400 and the second semiconductor chip 200.

The side molding portion 500a of the package molding layer 500 may extend in the first horizontal direction X to come into contact with the side cover portion 700a and extend in the second horizontal direction Y to come into contact with the side cover portion 700a.

Referring to FIG. 2B, the package molding cut MC may include only the plurality of first cuts. The plurality of first cuts of the package molding cut MC may be spaced apart from each other in the second horizontal direction Y with the second semiconductor chip 200 and the lower dummy support substrate 400 therebetween.

The side cover portion 700a of the cover layer 700 may extend along the package molding cut MC. The side cover portion 700a of the cover layer 700 may be spaced apart from the second semiconductor chip 200 and the lower dummy support substrate 400 in the second horizontal direction Y and may extend in the first horizontal direction X.

The side molding portion 500a of the package molding layer 500 may extend in the first horizontal direction X and may extend in the second horizontal direction Y to come into contact with the side cover portion 700a.

Referring to FIG. 2C, the package molding cut MC may include only the plurality of second cuts. The plurality of second cuts of the package molding cut MC may be spaced apart from each other in the first horizontal direction X with the second semiconductor chip 200 and the lower dummy support substrate 400 therebetween.

The side cover portion 700a of the cover layer 700 may extend along the package molding cut MC. The side cover portion 700a of the cover layer 700 may be spaced apart from the second semiconductor chip 200 and the lower dummy support substrate 400 in the first horizontal direction X and may extend in the second horizontal direction Y.

The side molding portion 500a of the package molding layer 500 may extend in the second horizontal direction Y and may extend in the first horizontal direction X to come into contact with the side cover portion 700a.

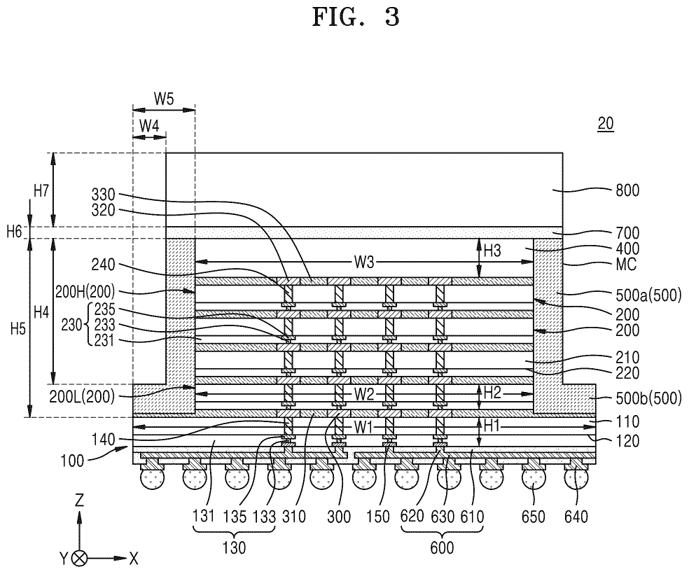

FIG. 3 is a cross-sectional view illustrating a semiconductor package 20 according to embodiments.

Since the semiconductor package 20 has a generally similar configuration to the semiconductor package 10 described above, the following description focuses on the differences between the semiconductor package 20 and the semiconductor package 10.

The semiconductor package 20 includes a first semiconductor chip 100 and a plurality of second semiconductor chips 200. The plurality of second semiconductor chips 200 may be sequentially stacked on the first semiconductor chip 100.

The first semiconductor chip 100 may include a first semiconductor substrate 110 having an active surface 120 and an inactive surface opposing each other, a first individual device disposed on the active surface 120 of the first semiconductor substrate 110, a first wiring structure 130 disposed on the active surface 120 of the first semiconductor substrate 110, and a plurality of first through-electrodes 140 connected to the first wiring structure 130 and penetrating through the first semiconductor substrate 110. The first wiring structure 130 may include a first wiring layer 131, a first wiring via 133, and a first wiring pattern 135. The first semiconductor chip 100 may further include a plurality of chip pads 150 which are arranged on the lower surface of the first semiconductor chip 100 and electrically connected to the first wiring structure 130.

In the semiconductor package 20, the first semiconductor chip 100 may be arranged such that the active surface 120 of the first semiconductor substrate 110 faces the bottom and the inactive surface of the first semiconductor substrate 110 faces the top.

Each of the second semiconductor chips 200 may include a second semiconductor substrate 210 having an active surface 220 and an inactive surface opposing each other, a second individual device disposed on the active surface 220 of the second semiconductor substrate 210, a second wiring structure 230 disposed on the active surface 220 of the second semiconductor substrate 210, and a plurality of second through-electrodes 240 connected to the second wiring structure 230 and penetrating through the second semiconductor substrate 210. The second wiring structure 230 may include a second wiring layer 231, a second wiring via 233, and a second wiring pattern 235.

The uppermost second semiconductor chip 200H among the plurality of second semiconductor chips 200 may include a plurality of support bonding pads 320 which are arranged on the upper surface of the uppermost second semiconductor chip 200H and electrically connected to the second wiring structure 230.

In the semiconductor package 20, the second semiconductor chip 200 may be arranged such that the active surface 220 of the second semiconductor substrate 210 faces the bottom and the inactive surface of the second semiconductor substrate 210 faces the top. For example, the second semiconductor chip 200 may be arranged such that the active surface 220 of the second semiconductor substrate 210 faces the inactive surface of the first semiconductor chip 100.

The first semiconductor chip 100 and the plurality of second semiconductor chips 200 may be electrically connected through a plurality of bonding pads 300 to exchange signals and provide power and ground. The plurality of bonding pads 300 may be arranged between the first semiconductor chip 100 and the lowermost second semiconductor chip 200L and between the plurality of second semiconductor chips 200 that are in contact with each other. A bonding insulating layer 310 may be located between the first semiconductor chip 100 and the lowermost second semiconductor chip 200L and between the plurality of second semiconductor chips 200 that are in contact with each other and may be adjacent to and surround the plurality of bonding pads 300. The plurality of bonding pads 300 may be adjacent to and surrounded by the bonding insulating layer 310 in a plan view.

Each of the plurality of bonding pads 300 may be arranged between the second wiring via 233 and/or the second wiring pattern 235 of the second wiring structure 230 and the first through-electrode 140 and between the second wiring via 233 and/or the second wiring pattern 235 of the second wiring structure 230 and the second through-electrode 240. The plurality of bonding pads 300 may electrically connect the second wiring vias 233 and/or the second wiring patterns 235 of the second wiring structure 230 to the first through-electrodes 140 or the second through-electrodes 240. For example, the plurality of bonding pads 300 may electrically connect the plurality of first through-electrodes 140 and the plurality of second through-electrodes 240 to each other.

A bonding insulating layer 310, which is located between the first semiconductor chip 100 and the lowermost second semiconductor chip 200L, among the plurality of bonding insulating layers 310 may be referred to as a lowermost bonding insulating layer 310. The lowermost bonding insulating layer 310 may include a portion overlapping the lowermost second semiconductor chip 200L in the vertical direction Z and a portion not overlapping the lowermost second semiconductor chip 200L in the vertical direction Z.

The height of the portion of the lowermost bonding insulating layer 310 in the vertical direction Z, which overlaps the lowermost second semiconductor chip 200L, may be greater than the height of the portion of the lowermost bonding insulating layer 310 in the vertical direction Z, which does not overlap the lowermost second semiconductor chip 200L.

The lowermost bonding insulating layer 310 may cover a portion of the upper surface of the first semiconductor chip 100 which does not overlap the lowermost second semiconductor chip 200L. The lowermost bonding insulating layer 310 may cover the upper surface of the first semiconductor chip 100 that is not covered and exposed by the plurality of bonding pads 300, at the portion of the upper surface of the first semiconductor chip 100 that overlaps the lowermost second semiconductor chip 200L.

The other bonding insulating layers 310 other than the lowermost bonding insulating layer 310 among the plurality of bonding insulating layers 310 may cover portions of the upper and lower surfaces of the second semiconductor chips 200, which are not covered by the plurality of bonding pads 300.

A lower dummy support substrate 400 may be disposed on the uppermost second semiconductor chip 200H. The lower dummy support substrate 400 may include, for example, a semiconductor material, such as silicon (Si).

The first semiconductor chip 100 may have a first width W1 in the first horizontal direction X and a first height H1 in the vertical direction Z. When the plurality of second semiconductor chips 200 has the substantially similar width in the first horizontal direction X and the substantially similar height in the vertical direction Z, each of the plurality of second semiconductor chips 200 may have a second width W2 in the first horizontal direction X and a second height H2 in the vertical direction Z. The lower dummy support substrate 400 may have a third width W3 in the first horizontal direction X and a third height H3 in the vertical direction Z. In embodiments, the first height H1, the second height H2, and the third height H3 and the first width W1, the second width W2, and the third width W3 may have the same relationships as those described above with reference to FIG. 1.

The plurality of support bonding pads 320 may be arranged between the uppermost second semiconductor chip 200H and the lower dummy support substrate 400. A support bonding insulating layer 330 may be located between the uppermost second semiconductor chip 200H and the lower dummy support substrate 400 and may be adjacent to and surround the plurality of support bonding pads 320. The plurality of support bonding pads 320 may be adjacent to and surrounded by the support bonding insulating layer 330 in a plan view.

The support bonding insulating layer 330 may cover portions of the upper surface of the uppermost second semiconductor chip 200H and the lower surface of the lower dummy support substrate 400, which are not covered by the plurality of support bonding pads 320.

In embodiments, the plurality of bonding pads 300 and the plurality of support bonding pads 320 may include the same materials as those described with reference to FIG. 1. In embodiments, the bonding insulating layers 310 and the support bonding insulating layer 330 may include the same materials as those described with reference to FIG. 1.

The semiconductor package 20 may include a package molding layer 500 that covers the portion of the upper surface of the first semiconductor chip 100 which is not covered and exposed by the lowermost second semiconductor chip 200L. The package molding layer 500 may be adjacent to and surround side walls of the plurality of second semiconductor chips 200 and side walls of the lower dummy support substrate 400. The package molding layer 500 may include, for example, an EMC.

The package molding layer 500 is shown as not covering and exposing the upper surface of the lower dummy support substrate 400, but embodiments are not limited thereto. The package molding layer 500 may cover the upper surface of the lower dummy support substrate 400.

The package molding layer 500 may include a bottom molding portion 500b covering a portion of the upper surface of the first semiconductor chip 100, which is not covered and exposed by the lowermost second semiconductor chip 200L, and a side molding portion 500a covering side walls of the plurality of second semiconductor chips 200 and side walls of the lower dummy support substrate 400. The side molding portion 500a and the bottom molding portion 500b may form a stepped structure. The side molding portion 500a may extend from the edge of the upper surface of the bottom molding portion 500b in the vertical direction Z and may extend to the side wall of the lower dummy support substrate 400. The side molding portion 500a may be in contact with the side walls of the plurality of second semiconductor chips 200 and the side walls of the lower dummy support substrate 400, and the bottom molding portion 500b may be in contact with the lowermost bonding insulating layer 310.

The side molding portion 500a may partially cover the upper surface of the bottom molding portion 500b. The width of the side molding portion 500a in the horizontal direction X or Y may be less than the width of the bottom molding portion 500b in the horizontal direction X or Y. For example, a width of the side molding portion 500a in the horizontal direction X or Y, which is obtained by subtracting W4 from W5 (i.e., W5−W4), may be less than a width W5 of the bottom molding portion 500b in the horizontal direction X or Y.

The package molding layer 500 may include a package molding cut MC. The side wall of the side molding portion 500a may be defined by the side wall of the package molding cut MC and the upper surface of the bottom molding portion 500b may be defined by the bottom of the package molding cut MC. The package molding cut MC may include a first molding cut facing the side walls of the plurality of second semiconductor chips 200 and a first side wall of the lower dummy support substrate 400 and a second molding cut facing a second side wall of the lower dummy support substrate 400 opposite to the first side wall.

The package molding cut MC may have a fourth width W4 in the first horizontal direction X and a fourth height H4 in the vertical direction Z. The package molding layer 500 may have a maximum fifth width W5 in the first horizontal direction X and a maximum fifth height H5 in the vertical direction Z. The fourth width W4 of the package molding cut MC may be less than the fifth width W5 of the package molding layer 500. The fourth height H4 of the package molding cut MC may be less than the fifth height H5 of the package molding layer 500. The fourth width W4 and fourth height H4 of the package molding cut MC may be adjusted by the width and height of a sawing blade, which is described below.

In embodiments, the semiconductor package 20 may further include a base redistribution layer 600 disposed on the lower surface of the first semiconductor chip 100. The base redistribution layer 600 may include a package redistribution insulating layer 610, a plurality of package redistribution vias 620, and a package redistribution line pattern 630.

A package pad 640 may be disposed on the lower surface of the base redistribution layer 600. In embodiments, the package pad 640 may include the same material as the package redistribution line pattern 630. The package pad 640 may be provided in plurality, and the plurality of package pads 640 may be respectively in contact with a plurality of package connection terminals 650. For example, each of the package connection terminals 650 may include a solder ball or a bump.

In embodiments, the semiconductor package 20 may not include the base redistribution layer 600. For example, the plurality of package connection terminals 650 may be attached to the plurality of chip pads 150.

The semiconductor package 20 may further include a cover layer 700 disposed on the package molding layer 500. The cover layer 700 may cover the upper surface of the side molding portion 500a of the package molding layer 500 and the upper surface of the lower dummy support substrate 400. The cover layer 700 may be in contact with the upper surface of the side molding portion 500a of the package molding layer 500 but may not be in contact with the side wall of the side molding portion 500a. The cover layer 700 may be spaced apart from the upper surface of the bottom molding portion 500b of the package molding layer 500.

The side molding portion 500a may be exposed through the side wall of the package molding cut MC and the bottom molding portion 500b may be exposed through the bottom of the package molding cut MC. For example, the side wall of the side molding portion 500a may be exposed and the upper surface of the bottom molding portion 500b may be exposed.

The cover layer 700 may have a width substantially equal to the difference between the first width W1 of the first semiconductor chip 100 and fourth widths W4 of the package molding cut MC in the first horizontal direction X. Also, the cover layer 700 may have a sixth height H6 in the vertical direction Z, and the sixth height H6 may be less than the first height H1 of the first semiconductor chip 100 or the second height H2 of each of the plurality of second semiconductor chips 200. The sixth height H6 may be about 4470 angstroms (Å).

In embodiments, the cover layer 700 may include an inorganic material, such as an oxide, but embodiments are not limited thereto. Any material may be included in the cover layer 700 as long as the material may fill a space between the lower dummy support substrate 400 and an upper dummy support substrate 800. For example, the cover layer 700 may include a metal, such as copper (Cu). In embodiments, the cover layer 700 may include a material different from that of the package molding layer 500.

The semiconductor package 20 may further include the upper dummy support substrate 800 that covers the upper surface of the cover layer 700. The upper dummy support substrate 800 may include, for example, a semiconductor material, such as silicon (Si). The upper dummy support substrate 800 may include only the semiconductor material. For example, the upper dummy support substrate 800 may include a portion of a bare wafer.

The upper dummy support substrate 800 may have a width substantially equal to the difference between the first width W1 of the first semiconductor chip 100 and the fourth widths W4 of the package molding cut MC in the first horizontal direction X. For example, the upper dummy support substrate 800 may have substantially the same width as the cover layer 700 in the first horizontal direction X. The upper dummy support substrate 800 may have a seventh height H7 in the vertical direction Z. The seventh height H7 of the upper dummy support substrate 800 may be greater than the sum of the first height H1 and the second height H2. The seventh height H7 of the upper dummy support substrate 800 may be about 110 micrometers to about 620 micrometers.

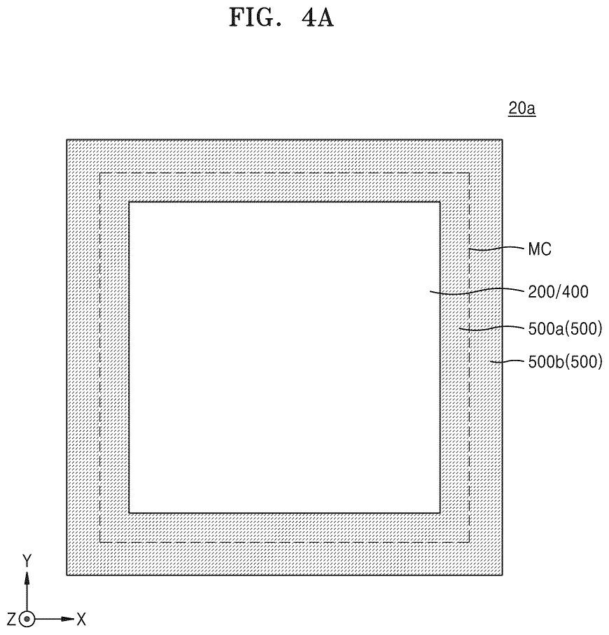

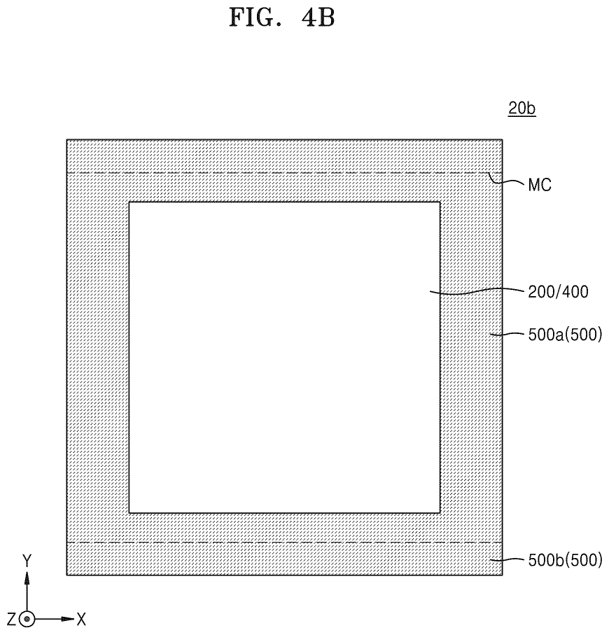

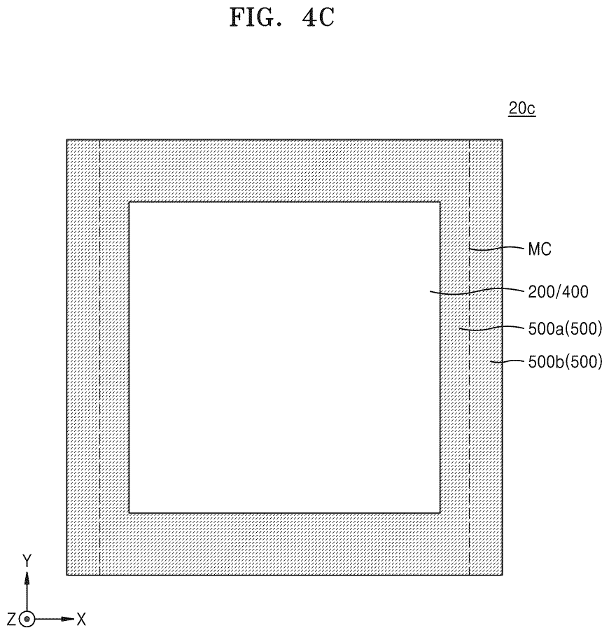

FIGS. 4A, 4B, and 4C are layouts illustrating semiconductor packages 20a, 20b, and 20c according to embodiments.

Referring to FIGS. 4A, 4B, and 4C, a package molding layer 500 may be adjacent to and surround a plurality of second semiconductor chips 200 and a lower dummy support substrate 400. The plurality of second semiconductor chips 200 and the lower dummy support substrate 400 may be adjacent to and surrounded by the package molding layer 500 in a plan view. Referring to FIG. 3 together, the side molding portion 500a of the package molding layer 500 may be adjacent to and surround the side walls of the plurality of second semiconductor chips 200 and the lower dummy support substrate 400. The bottom molding portion 500b of the package molding layer 500 may be provided below the side cover portion 700a of the cover layer 700 and may be adjacent to and surround portions of the side walls of the plurality of second semiconductor chips 200 and the lower dummy support substrate 400, which are not be adjacent to and surrounded by the side molding portion 500a.

The package molding cut MC may include a plurality of first cuts extending in the first horizontal direction X or a plurality of second cuts extending in the second horizontal direction Y.

Referring to FIG. 4A, the package molding cut MC may include the plurality of first cuts and the plurality of second cuts. In the package molding cut MC, the plurality of first cuts may be spaced apart from each other in the second horizontal direction Y with the second semiconductor chip 200 and the lower dummy support substrate 400 therebetween and the plurality of second cuts may be spaced apart from each other in the first horizontal direction X with the second semiconductor chip 200 and the lower dummy support substrate 400 therebetween. At least one of the plurality of first cuts may be connected to at least one of the plurality of second cuts. However, the plurality of first cuts are not necessarily connected to the plurality of second cuts, and the plurality of first cuts and the plurality of second cuts may not be connected to each other.

The side molding portion 500a of the package molding layer 500 may extend in the first horizontal direction X to come into contact with the package molding cut MC and extend in the second horizontal direction Y to come into contact with the package molding cut MC.

Referring to FIG. 4B, the package molding cut MC may include only the plurality of first cuts. The plurality of first cuts of the package molding cut MC may be spaced apart from each other in the second horizontal direction Y with the second semiconductor chip 200 and the lower dummy support substrate 400 therebetween.

The side molding portion 500a of the package molding layer 500 may extend in the first horizontal direction X and may extend in the second horizontal direction Y to come into contact with the package molding cut MC.

Referring to FIG. 4C, the package molding cut MC may include only the plurality of second cuts. The plurality of second cuts of the package molding cut MC may be spaced apart from each other in the first horizontal direction X with the second semiconductor chip 200 and the lower dummy support substrate 400 therebetween.

The side molding portion 500a of the package molding layer 500 may extend in the second horizontal direction Y and may extend in the first horizontal direction X to come into contact with the package molding cut MC.

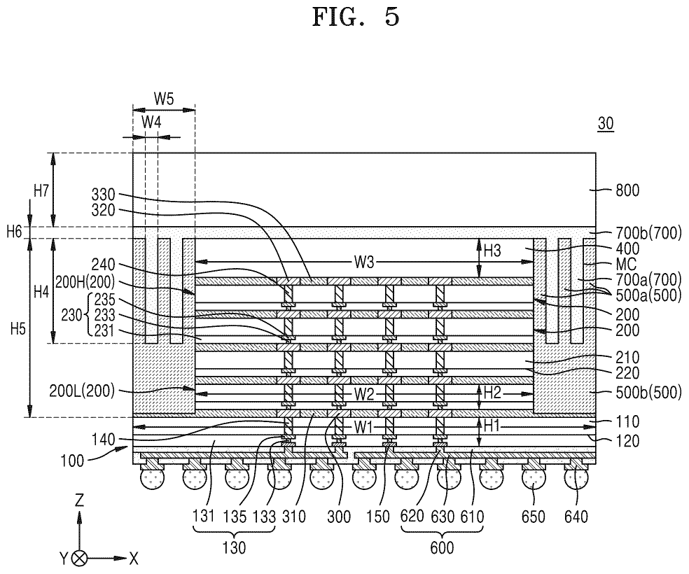

FIG. 5 is a cross-sectional view illustrating a semiconductor package 30 according to embodiments.

Since the semiconductor package 30 has a generally similar configuration to the semiconductor package 10 described above, the following description focuses on the differences between the semiconductor package 30 and the semiconductor package 10.

The semiconductor package 30 includes a first semiconductor chip 100 and a plurality of second semiconductor chips 200. The plurality of second semiconductor chips 200 may be sequentially stacked on the first semiconductor chip 100.

The first semiconductor chip 100 may include a first semiconductor substrate 110 having an active surface 120 and an inactive surface opposing each other, a first individual device disposed on the active surface 120 of the first semiconductor substrate 110, a first wiring structure 130 disposed on the active surface 120 of the first semiconductor substrate 110, and a plurality of first through-electrodes 140 connected to the first wiring structure 130 and penetrating through the first semiconductor substrate 110. The first wiring structure 130 may include a first wiring layer 131, a first wiring via 133, and a first wiring pattern 135. The first semiconductor chip 100 may further include a plurality of chip pads 150 which are arranged on the lower surface of the first semiconductor chip 100 and electrically connected to the first wiring structure 130.

In the semiconductor package 30, the first semiconductor chip 100 may be arranged such that the active surface 120 of the first semiconductor substrate 110 faces the bottom and the inactive surface of the first semiconductor substrate 110 faces the top.

Each of the second semiconductor chips 200 may include a second semiconductor substrate 210 having an active surface 220 and an inactive surface opposing each other, a second individual device disposed on the active surface 220 of the second semiconductor substrate 210, a second wiring structure 230 disposed on the active surface 220 of the second semiconductor substrate 210, and a plurality of second through-electrodes 240 connected to the second wiring structure 230 and penetrating through the second semiconductor substrate 210. The second wiring structure 230 may include a second wiring layer 231, a second wiring via 233, and a second wiring pattern 235.

The uppermost second semiconductor chip 200H among the plurality of second semiconductor chips 200 may include a plurality of support bonding pads 320 which are arranged on the upper surface of the uppermost second semiconductor chip 200H and electrically connected to the second wiring structure 230.

In the semiconductor package 30, the second semiconductor chip 200 may be arranged such that the active surface 220 of the second semiconductor substrate 210 faces the bottom and the inactive surface of the second semiconductor substrate 210 faces the top. For example, the second semiconductor chip 200 may be arranged such that the active surface 220 of the second semiconductor substrate 210 faces the inactive surface of the first semiconductor chip 100.

The first semiconductor chip 100 and the plurality of second semiconductor chips 200 may be electrically connected through a plurality of bonding pads 300 to exchange signals and provide power and ground. The plurality of bonding pads 300 may be arranged between the first semiconductor chip 100 and the lowermost second semiconductor chip 200L and between the plurality of second semiconductor chips 200 that are in contact with each other. A bonding insulating layer 310 may be located between the first semiconductor chip 100 and the lowermost second semiconductor chip 200L and between the plurality of second semiconductor chips 200 that are in contact with each other and may be adjacent to and surround the plurality of bonding pads 300. The plurality of bonding pads 300 may be adjacent to and surrounded by the bonding insulating layer 310 in a plan view.

Each of the plurality of bonding pads 300 may be arranged between the second wiring via 233 and/or the second wiring pattern 235 of the second wiring structure 230 and the first through-electrode 140 and between the second wiring via 233 and/or the second wiring pattern 235 of the second wiring structure 230 and the second through-electrode 240. The plurality of bonding pads 300 may electrically connect the second wiring vias 233 and/or the second wiring patterns 235 of the second wiring structure 230 to the first through-electrodes 140 or the second through-electrodes 240.

A bonding insulating layer 310, which is located between the first semiconductor chip 100 and the lowermost second semiconductor chip 200L, among the plurality of bonding insulating layers 310 may be referred to as a lowermost bonding insulating layer 310. The lowermost bonding insulating layer 310 may include a portion overlapping the lowermost second semiconductor chip 200L in the vertical direction Z and a portion not overlapping the lowermost second semiconductor chip 200L in the vertical direction Z.

The height of the portion of the lowermost bonding insulating layer 310 in the vertical direction Z, which overlaps the lowermost second semiconductor chip 200L, may be greater than the height of the portion of the lowermost bonding insulating layer 310 in the vertical direction Z, which does not overlap the lowermost second semiconductor chip 200L.

The lowermost bonding insulating layer 310 may cover a portion of the upper surface of the first semiconductor chip 100 which does not overlap the lowermost second semiconductor chip 200L. The lowermost bonding insulating layer 310 may cover the upper surface of the first semiconductor chip 100 that is not covered by the plurality of bonding pads 300, at the portion of the upper surface of the first semiconductor chip 100 that overlaps the lowermost second semiconductor chip 200L.

The other bonding insulating layers 310 other than the lowermost bonding insulating layer 310 among the plurality of bonding insulating layers 310 may cover portions of the upper and lower surfaces of the second semiconductor chips 200, which are not covered by the plurality of bonding pads 300.

A lower dummy support substrate 400 may be disposed on the uppermost second semiconductor chip 200H. The lower dummy support substrate 400 may include, for example, a semiconductor material, such as silicon (Si).

The first semiconductor chip 100 may have a first width W1 in the first horizontal direction X and a first height H1 in the vertical direction Z. When the plurality of second semiconductor chips 200 has the substantially similar width in the first horizontal direction X and the substantially similar height in the vertical direction Z, each of the plurality of second semiconductor chips 200 may have a second width W2 in the first horizontal direction X and a second height H2 in the vertical direction Z. The lower dummy support substrate 400 may have a third width W3 in the first horizontal direction X and a third height H3 in the vertical direction Z.

In embodiments, the first height H1, the second height H2, and the third height H3 and the first width W1, the second width W2, and the third width W3 may have the same values as those described above with reference to FIG. 1.

The plurality of support bonding pads 320 may be arranged between the uppermost second semiconductor chip 200H and the lower dummy support substrate 400. A support bonding insulating layer 330 may be located between the uppermost second semiconductor chip 200H and the lower dummy support substrate 400 and may be adjacent to and surround the plurality of support bonding pads 320. The plurality of support bonding pads 320 may be adjacent to and surrounded by the support bonding insulating layer 330 in a plan view.

The support bonding insulating layer 330 may cover portions of the upper surface of the uppermost second semiconductor chip 200H and the lower surface of the lower dummy support substrate 400, which are not covered by the plurality of support bonding pads 320.

In embodiments, the plurality of bonding pads 300 and the plurality of support bonding pads 320 may include the same materials as those described with reference to FIG. 1. In embodiments, the bonding insulating layers 310 and the support bonding insulating layer 330 may include the same materials as those described with reference to FIG. 1.

The semiconductor package 30 may include a package molding layer 500 that covers the portion of the upper surface of the first semiconductor chip 100 which is not covered and exposed by the lowermost second semiconductor chip 200L. The package molding layer 500 may be adjacent to and surround side walls of the plurality of second semiconductor chips 200 and side walls of the lower dummy support substrate 400. The package molding layer 500 may include, for example, an EMC.

The package molding layer 500 is shown as not covering the upper surface of the lower dummy support substrate 400, but embodiments are not limited thereto. The package molding layer 500 may cover the upper surface of the lower dummy support substrate 400.

The package molding layer 500 may include a bottom molding portion 500b covering a portion of the upper surface of the first semiconductor chip 100, which is not covered and exposed by the lowermost second semiconductor chip 200L, and a plurality of side molding portions 500a covering side walls of the plurality of second semiconductor chips 200 and side walls of the lower dummy support substrate 400. The plurality of side molding portions 500a may extend from the edge of the upper surface of the bottom molding portion 500b in the vertical direction Z and may extend to the side wall of the lower dummy support substrate 400. One of the plurality of side molding portions 500a may be in contact with the side walls of the plurality of second semiconductor chips 200 and the side walls of the lower dummy support substrate 400, and the bottom molding portion 500b may be in contact with the lowermost bonding insulating layer 310.

The plurality of side molding portions 500a may partially cover the upper surface of the bottom molding portion 500b. The sum of widths of the plurality of side molding portions 500a in the horizontal direction X or Y may be less than the width of the bottom molding portion 500b in the horizontal direction X or Y. For example, when three side molding portions 500a are arranged on the first side wall of the lower dummy support substrate 400, the sum (W5−(W4)×2) of the widths of the plurality of side molding portions 500a in the horizontal direction X or Y may be less than a width W5 of the bottom molding portion 500b in the horizontal direction X or Y.

When the lower dummy support substrate 400 includes a first side wall and a second side wall opposing the first side wall, the package molding layer 500 may include a plurality of package molding cuts MC on the first side wall. The plurality of package molding cuts MC may include two or more package molding cuts MC, but embodiments are not limited to that shown in the diagram. For example, the plurality of package molding cuts MC may include three package molding cuts MC. The side walls of the plurality of side molding portions 500a may be respectively defined by the side walls of the plurality of package molding cuts MC and the upper surfaces of the bottom molding portion 500b may be defined by the bottoms of the plurality of package molding cuts MC.

The plurality of package molding cuts MC may each have a fourth width W4 in the first horizontal direction X and a fourth height H4 in the vertical direction Z. The package molding layer 500 may have a fifth width W5 in the first horizontal direction X and a fifth height H5 in the vertical direction Z. The fourth width W4 of each of the plurality of package molding cuts MC may be less than the fifth width W5 of the package molding layer 500. Also, the sum of fourth widths W4 of the plurality of package molding cuts MC may be less than the fifth width W5 of the package molding layer 500. The fourth widths W4 of the plurality of package molding cuts MC may be substantially equal to each other, but embodiments are not limited thereto. For example, the fourth widths W4 of the plurality of package molding cuts MC may be different from each other.

The fourth height H4 of each of the plurality of package molding cuts MC may be less than the fifth height H5 of the package molding layer 500. The fourth heights H4 of the plurality of package molding cuts MC may be substantially equal to each other, but embodiments are not limited thereto. For example, the fourth heights H4 of the plurality of package molding cuts MC may be different from each other.

The fourth width W4 and fourth height H4 of each of the plurality of package molding cuts MC may be adjusted by the width and height of a sawing blade, which is described below.

In embodiments, the semiconductor package 30 may further include a base redistribution layer 600 disposed on the lower surface of the first semiconductor chip 100. The base redistribution layer 600 may include a package redistribution insulating layer 610, a plurality of package redistribution vias 620, and a package redistribution line pattern 630.

A package pad 640 may be disposed on the lower surface of the base redistribution layer 600. In embodiments, the package pad 640 may include the same material as the package redistribution line pattern 630. The package pad 640 may be provided in plurality, and the plurality of package pads 640 may be respectively in contact with a plurality of package connection terminals 650. For example, each of the package connection terminals 650 may include a solder ball or a bump.

In embodiments, the semiconductor package 30 may not include the base redistribution layer 600. For example, the plurality of package connection terminals 650 may be attached to the plurality of chip pads 150.

The semiconductor package 30 may further include a cover layer 700 disposed on the package molding layer 500. The cover layer 700 may cover the upper surface of the lower dummy support substrate 400 and the upper surface of the package molding layer 500 and may extend and fill the interior of the package molding cut MC.

The cover layer 700 may include a plurality of side cover portions 700a respectively covering the side walls of the plurality of side molding portions 500a and the upper surfaces of the bottom molding portion 500b and a top cover portion 700b covering the upper surface of the lower dummy support substrate 400 and the upper surfaces of the side molding portions 500a. The plurality of side cover portions 700a may extend from the top cover portion 700b toward the bottom molding portion 500b and may extend to respectively come into contact with the upper surfaces of the bottom molding portion 500b. The plurality of side cover portions 700a may overlap the lower dummy support substrate 400 or the plurality of second semiconductor chips 200 in the horizontal direction X or Y and may overlap the plurality of side molding portions 500a in the horizontal direction X or Y. The plurality of side cover portions 700a may be spaced apart from the lower dummy support substrate 400 or the plurality of second semiconductor chips 200 in the horizontal direction X or Y. The side molding portion 500a may be located between the side cover portion 700a and the lower dummy support substrate 400 or the plurality of second semiconductor chips 200 and between the side cover portions 700a adjacent to each other.

The cover layer 700 may be in contact with the side molding portions 500a respectively through the side walls of the package molding cuts MC and may be in contact with the bottom molding portion 500b through the bottoms of the package molding cuts MC. For example, the side walls of the plurality of side molding portions 500a may be respectively in contact with the side walls of the plurality of side cover portions 700a and the upper surfaces of the bottom molding portion 500b may be respectively in contact with the bottoms of the plurality of side cover portions 700a.

In embodiments, the cover layer 700 may include an inorganic material, such as an oxide, but embodiments are not limited thereto. Any material may be included in the cover layer 700 as long as the material may fill a space between the lower dummy support substrate 400 and an upper dummy support substrate 800. For example, the cover layer 700 may include a metal, such as copper (Cu).

The side cover portion 700a of the cover layer 700 may each have the fourth width W4 in the first horizontal direction X. The fourth width W4 may be equal to the width of each of the plurality of package molding cuts MC in the first horizontal direction X. The top cover portion 700b of the cover layer 700 may have a width substantially equal to the first width W1 of the first semiconductor chip 100 in the first horizontal direction X. Also, each of the plurality of the side cover portions 700a of the cover layer 700 may have the fourth height H4 in the vertical direction Z. The fourth height H4 may be equal to the height of the package molding cut MC in the vertical direction Z. The top cover portion 700b of the cover layer 700 may have a sixth height H6 in the vertical direction Z. The sixth height H6 of the top cover portion 700b may be less than the first height H1 of the first semiconductor chip 100 or the second height H2 of each of the plurality of second semiconductor chips 200. For example, the sixth height H6 of the top cover portion 700b may be about 4470 angstroms.

The semiconductor package 30 may further include the upper dummy support substrate 800 that covers the upper surface of the cover layer 700. The upper dummy support substrate 800 may include, for example, a semiconductor material, such as silicon (Si). The upper dummy support substrate 800 may include only the semiconductor material. For example, the upper dummy support substrate 800 may include a portion of a bare wafer.

The upper dummy support substrate 800 may have a width substantially equal to the first width W1 of the first semiconductor chip 100 in the first horizontal direction X. For example, the upper dummy support substrate 800 may have substantially the same width as the top cover portion 700b of the cover layer 700 in the first horizontal direction X. The upper dummy support substrate 800 may have a seventh height H7 in the vertical direction Z. The seventh height H7 of the upper dummy support substrate 800 may be greater than the sum of the first height H1 and the second height H2. The seventh height H7 of the upper dummy support substrate 800 may be about 110 micrometers to about 620 micrometers.

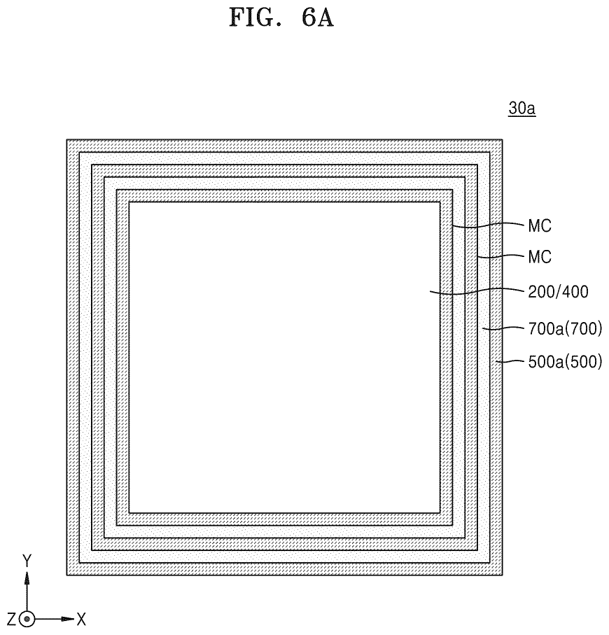

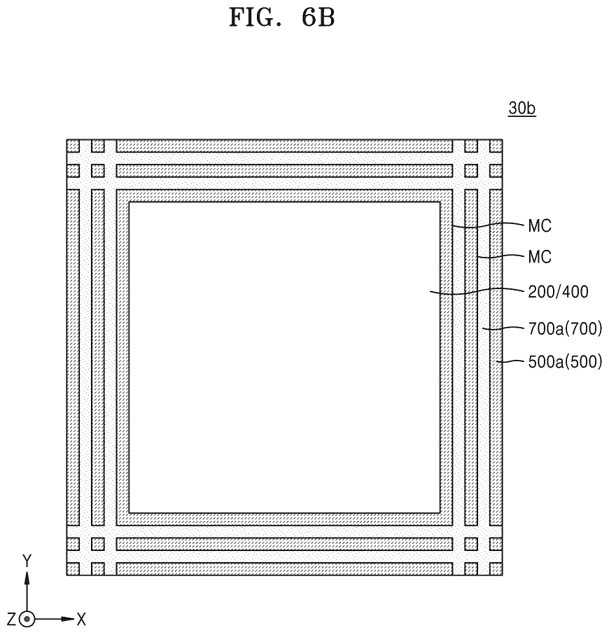

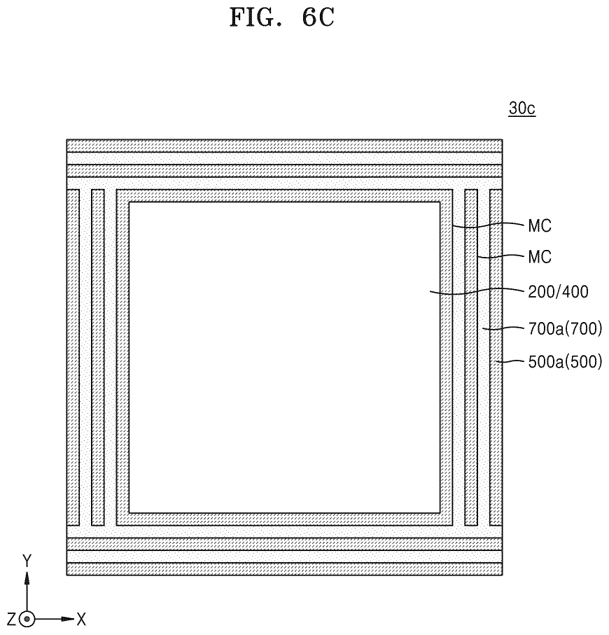

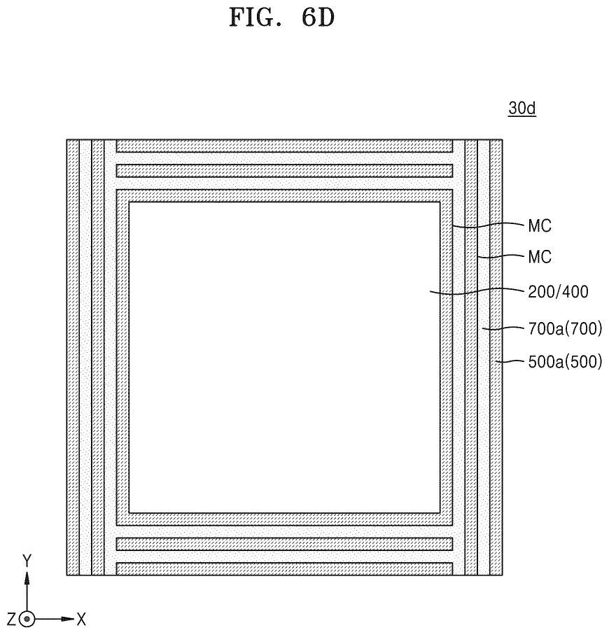

FIGS. 6A, 6B, 6C, and 6D are layouts illustrating semiconductor packages 30a, 30b, 30c, and 30d according to embodiments.

Referring to FIGS. 6A, 6B, 6C, and 6D, a package molding layer 500 may be adjacent to and surround a plurality of second semiconductor chips 200 and a lower dummy support substrate 400. The plurality of second semiconductor chips 200 and the lower dummy support substrate 400 may be adjacent to and surrounded by the package molding layer 500 in a plan view. Referring to FIG. 5 together, the plurality of side molding portions 500a of the package molding layer 500 may be adjacent to and surround the side walls of the plurality of second semiconductor chips 200 and the lower dummy support substrate 400. The bottom molding portion 500b of the package molding layer 500 may be provided below the plurality of side cover portions 700a of the cover layer 700 and may be adjacent to and surround portions of the side walls of the plurality of second semiconductor chips 200 and the lower dummy support substrate 400, which are not be adjacent to and surrounded by the plurality of side molding portions 500a.

The package molding layer 500 may include a plurality of package molding cuts MC on one side surface of the four side surfaces of the lower dummy support substrate 400. A plurality of package molding cuts MC facing the four surfaces of the lower dummy support substrate 400 may be respectively referred to as a first group, a second group, a third group, and a fourth group. The first group may be spaced apart from the second group with the lower dummy support substrate 400 therebetween and the third group may be spaced apart from the fourth group with the lower dummy support substrate 400 therebetween. Referring to FIG. 6A, the first group and the second group may be connected to each other by the third group and the fourth group. However, the plurality of package molding cuts MC constituting the first group are not necessarily connected to the plurality of package molding cuts MC constituting the second group, and the first group and the second group may not be connected to each other.

The plurality of side cover portions 700a of the cover layer 700 may respectively extend along the plurality of package molding cuts MC.

The plurality of side molding portions 500a of the package molding layer 500 may extend in the first horizontal direction X to come into contact with the side cover portion 700a and extend in the second horizontal direction Y to come into contact with the side cover portion 700a. Referring to FIG. 6B, the first group and the second group may be connected to each other by the third group and the fourth group. Here, the first group may extend while penetrating through the third group or the fourth group and the second group may extend while penetrating through the third group or the fourth group. However, the plurality of package molding cuts MC constituting the first group are not necessarily connected to the plurality of package molding cuts MC constituting the second group, and the first group and the second group may not be connected to each other.

The plurality of side cover portions 700a of the cover layer 700 may respectively extend along the plurality of package molding cuts MC.

The plurality of side molding portions 500a of the package molding layer 500 may extend in the first horizontal direction X to come into contact with the side cover portion 700a and extend in the second horizontal direction Y to come into contact with the side cover portion 700a.

Referring to FIGS. 6C and 6D, the first group and the second group may extend in the first horizontal direction X and the third group and the fourth group may extend in the second horizontal direction Y so that the third group and the fourth group are connected to the first group and the second group. Also, the first group and the second group may extend in the second horizontal direction Y and the third group and the fourth group may extend in the first horizontal direction X so that the third group and the fourth group are connected to the first group and the second group.

The plurality of side cover portions 700a of the cover layer 700 may respectively extend along the plurality of package molding cuts MC.

The plurality of side molding portions 500a of the package molding layer 500 may extend in the first horizontal direction X to come into contact with the side cover portion 700a and extend in the second horizontal direction Y to come into contact with the side cover portion 700a.

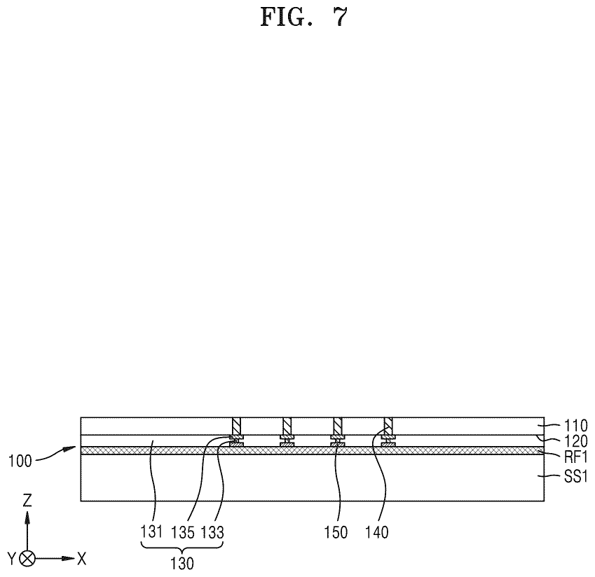

FIGS. 7 to 14, 15A, 15B, 16A, 16B, 17A, and 17B are cross-sectional views illustrated in process order to describe a method of manufacturing a semiconductor package, according to embodiments.

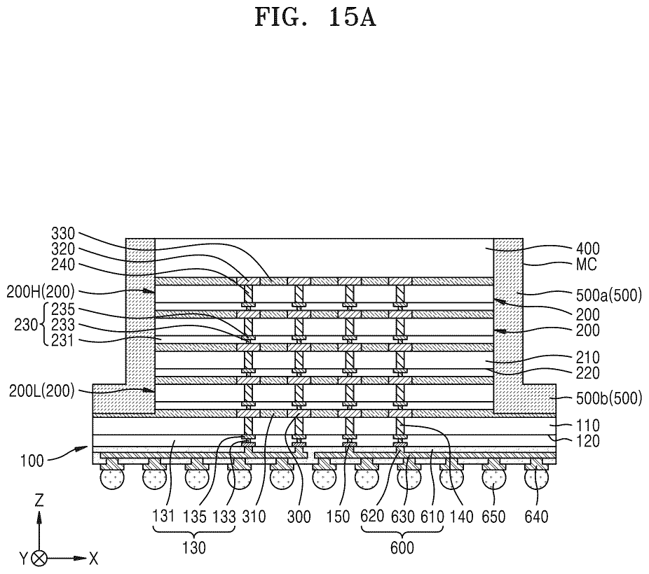

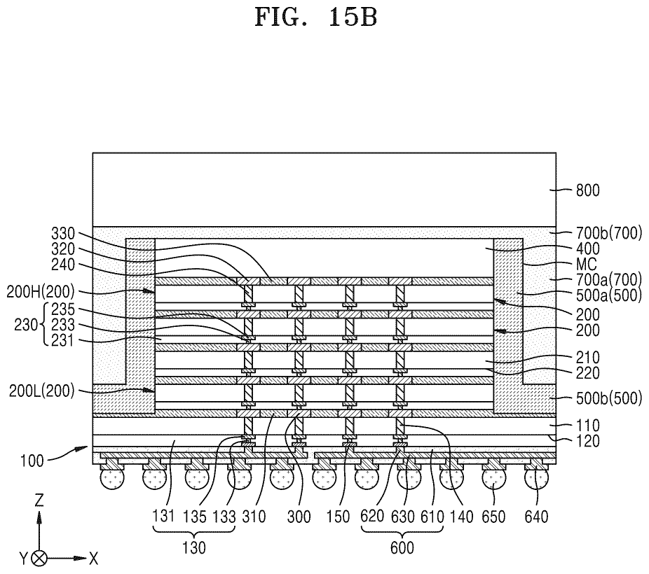

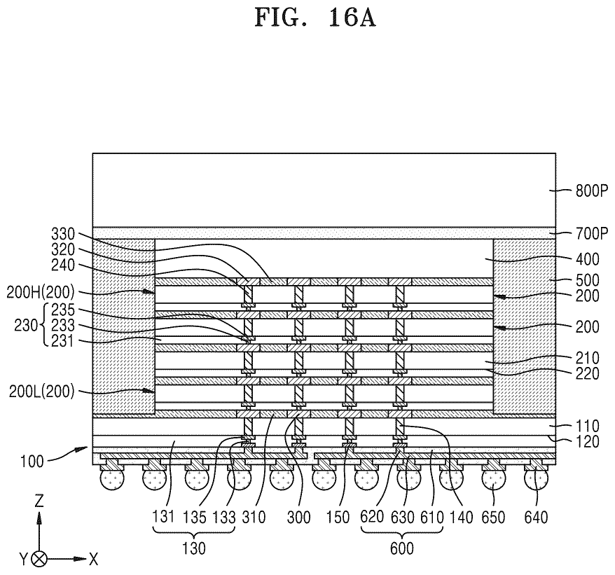

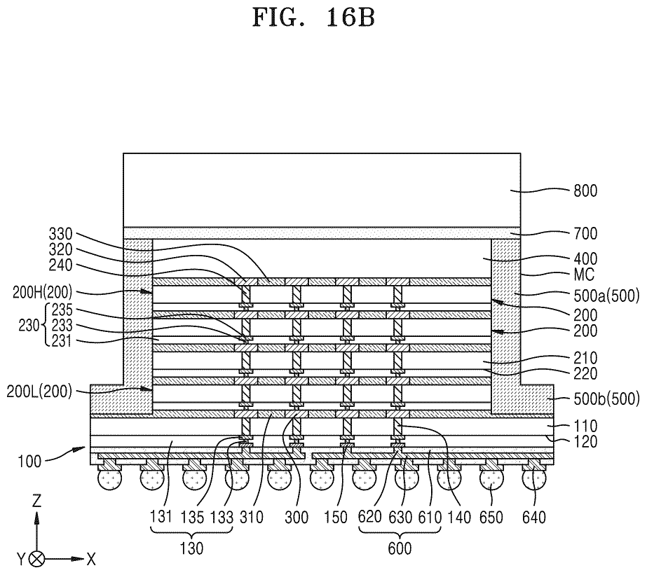

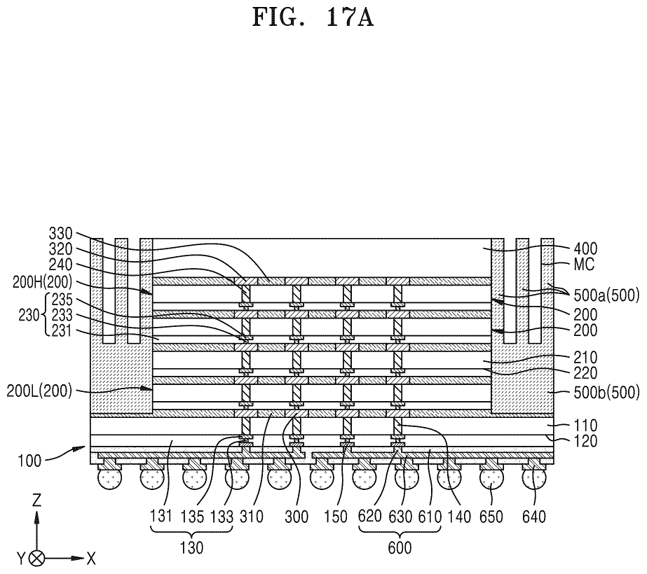

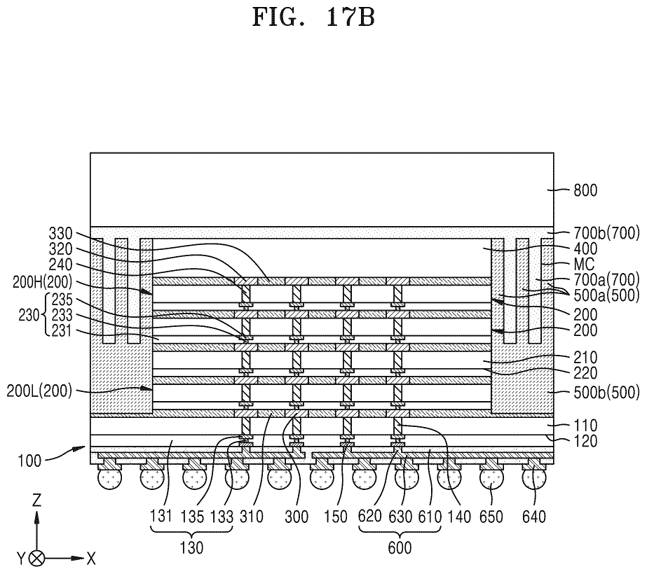

For example, FIGS. 15A and 15B are cross-sectional views for explaining a method of manufacturing the semiconductor package 10 shown in FIG. 1, FIGS. 16A and 16B are cross-sectional views for explaining a method of manufacturing the semiconductor package 20 shown in FIG. 3, and FIGS. 17A and 17B are cross-sectional views for explaining a method of manufacturing the semiconductor package 30 shown in FIG. 5. Repeated descriptions as those given with reference to FIGS. 1, 3, and 5 are omitted.

Referring to FIG. 7, a first semiconductor chip 100 is attached to a first support substrate SS1. After a first release film RF1 is attached to the upper surface of the first support substrate SS1, the first semiconductor chip 100 may be attached on the first release film RF1. The first semiconductor chip 100 may be attached to the first release film RF1 such that a first wiring structure 130 faces the first support substrate SS1. A plurality of chip pads 150 exposed on the lower surface of the first semiconductor substrate 110 may be attached to the first release film RF1.

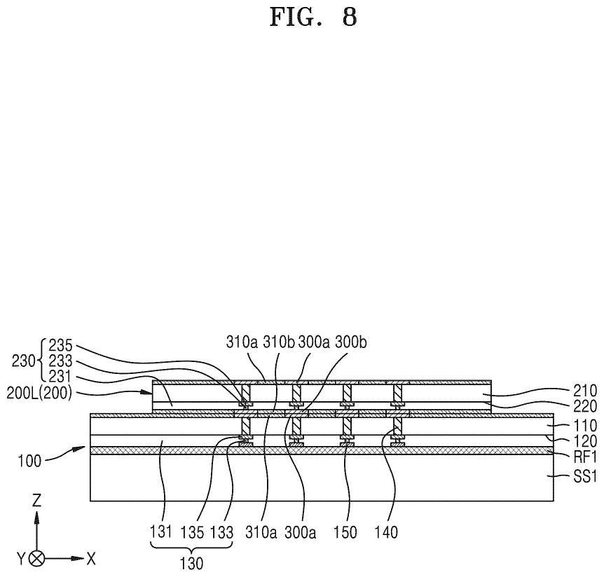

Referring to FIG. 8, a plurality of first preliminary bonding pads 300a and a first preliminary bonding insulating layer 310a are formed on the upper surface of the first semiconductor chip 100. The plurality of first preliminary bonding pads 300a may be arranged on the upper surface, for example, the inactive surface, of the first semiconductor chip 100. The plurality of first preliminary bonding pads 300a may be disposed on the upper surface of the first semiconductor chip 100 so that the first preliminary bonding pads 300a are respectively connected to a plurality of first through-electrodes 140. The first preliminary bonding insulating layer 310a may be formed on the upper surface, for example, the inactive surface, of the first semiconductor chip 100 and be adjacent to and surround side surfaces of the plurality of first preliminary bonding pads 300a. The first preliminary bonding insulating layer 310a may cover the upper surface of the first semiconductor chip 100 and the side surfaces of the plurality of first preliminary bonding pads 300a but may expose the plurality of first preliminary bonding pads 300a without covering the upper surfaces of the first preliminary bonding pads 300a.

A plurality of first preliminary bonding pads 300a and a first preliminary bonding insulating layer 310a are also formed on the upper surface of a lowermost second semiconductor chip 200L. The plurality of first preliminary bonding pads 300a may be disposed on the upper surface, for example, the inactive surface, of the lowermost second semiconductor chip 200L. The plurality of first preliminary bonding pads 300a may be disposed on the upper surface of the lowermost second semiconductor chip 200L so that the first preliminary bonding pads 300a are respectively connected to a plurality of second through-electrodes 240. The first preliminary bonding insulating layer 310a may be formed on the upper surface, for example, the inactive surface, of the lowermost second semiconductor chip 200L and be adjacent to and surround side surfaces of the plurality of first preliminary bonding pads 300a. The first preliminary bonding insulating layer 310a may cover the upper surface of the lowermost second semiconductor chip 200L and the side surfaces of the plurality of first preliminary bonding pads 300a but may expose the plurality of first preliminary bonding pads 300a without covering the upper surfaces of the first preliminary bonding pads 300a.

A plurality of second preliminary bonding pads 300b and a second preliminary bonding insulating layer 310b are formed on the lower surface of the lowermost second semiconductor chip 200L. The plurality of second preliminary bonding pads 300b may be disposed on the lower surface of the lowermost second semiconductor chip 200L, for example, the lower surface of a second wiring structure 230. The plurality of second preliminary bonding pads 300b may be disposed on the lower surface of the lowermost second semiconductor chip 200L so that the second preliminary bonding pads 300b are respectively connected to second wiring vias 233 and/or second wiring patterns 235. The second preliminary bonding insulating layer 310b may be formed on the lower surface of the lowermost second semiconductor chip 200L and be adjacent to and surround side surfaces of the plurality of second preliminary bonding pads 300b. The second preliminary bonding insulating layer 310b may cover the lower surface of lowermost second semiconductor chip 200L and the side surfaces of the plurality of second preliminary bonding pads 300b but may expose the plurality of second preliminary bonding pads 300b without covering the lower surfaces of the second preliminary bonding pads 300b.

Referring to FIG. 9, the lowermost second semiconductor chip 200L is placed on the first semiconductor chip 100, and then heat, pressure, or a combination thereof are applied to the lowermost second semiconductor chip 200L and the first semiconductor chip 100. Accordingly, the plurality of first preliminary bonding pads 300a and the plurality of second preliminary bonding pads 300b may be bonded to each other and the first preliminary bonding insulating layer 310a and the second preliminary bonding insulating layer 310b may be bonded to each other. In embodiments, the plurality of first preliminary bonding pads 300a and the plurality of second preliminary bonding pads 300b may be bonded to each other by forming covalent bonds, and the first preliminary bonding insulating layer 310a and the second preliminary bonding insulating layer 310b may be bonded to each other by forming covalent bonds.

In embodiments, the lowermost second semiconductor chip 200L may be placed on the first semiconductor chip 100, and then heat at a first temperature may be applied to the lowermost second semiconductor chip 200L and the first semiconductor chip 100. Subsequently, heat at a second temperature higher than the first temperature is applied to the lowermost second semiconductor chip 200L and the first semiconductor chip 100. Accordingly, the plurality of bonding pads 300 may be formed by coupling the plurality of first preliminary bonding pads 300a and the plurality of corresponding second preliminary bonding pads 300b to each other and the bonding insulating layer 310 may be formed by coupling the first preliminary bonding insulating layer 310a and the second preliminary bonding insulating layer 310b to each other.

The plurality of first preliminary bonding pads 300a and the plurality of second preliminary bonding pads 300b, which correspond to each other, may be expanded by heat and brought into contact with each other, and the plurality of first preliminary bonding pads 300a and the plurality of second preliminary bonding pads 300b may be integrated with each other by diffusion bonding using diffusion of metal atoms. Accordingly, the plurality of bonding pads 300 may be formed. Similarly, the first preliminary bonding insulating layer 310a and the second preliminary bonding insulating layer 310b may be brought into contact with each other, and then integrated with each other by diffusion bonding using diffusion of atoms. Accordingly, the bonding insulating layer 310 may be formed. The lowermost second semiconductor chip 200L may be attached to the first semiconductor chip 100 by the plurality of bonding pads 300 and the bonding insulating layer 310.

The width of the first preliminary bonding insulating layer 310a on the upper surface of the first semiconductor chip 100 in the first horizontal direction X may be substantially equal to the first width W1 (FIG. 1) of the first semiconductor chip 100 in the first horizontal direction X. The width of the second preliminary bonding insulating layer 310b on the lower surface of the lowermost second semiconductor chip 200L in the first horizontal direction X may be substantially equal to the second width W2 (FIG. 1) of the lowermost second semiconductor chip 200L in the first horizontal direction X. Therefore, a portion of the first preliminary bonding insulating layer 310a on the upper surface of the first semiconductor chip 100 may be in contact with the second preliminary bonding insulating layer 310b on the lower surface of the lowermost second semiconductor chip 200L and may form the bonding insulating layer 310. However, the other portions of the first preliminary bonding insulating layer 310a on the upper surface of the first semiconductor chip 100 may not be in contact with the second preliminary bonding insulating layer 310b on the lower surface of the lowermost second semiconductor chip 200L. The portion of the first preliminary bonding insulating layer 310a on the upper surface of the first semiconductor chip 100, which is in contact with the second preliminary bonding insulating layer 310b on the lower surface of the lowermost second semiconductor chip 200L, may overlap the lowermost second semiconductor chip 200L in the vertical direction Z.

Subsequently, a plurality of second semiconductor chips 200 are sequentially placed on the lowermost second semiconductor chip 200L that is located on the first semiconductor chip 100. A plurality of second preliminary bonding pads 300b and a second preliminary bonding insulating layer 310b may be formed on each of the lower surfaces of the plurality of second semiconductor chips 200 that are sequentially placed on the lowermost second semiconductor chip 200L. Also, a plurality of first preliminary bonding pads 300a and a first preliminary bonding insulating layer 310a may be formed on each of the upper surfaces of the second semiconductor chips 200 except for the uppermost second semiconductor chip 200H among the plurality of second semiconductor chips 200. A first preliminary support bonding pad 320a and a first preliminary support bonding insulating layer 330a may be formed on the uppermost second semiconductor chip 200H.

Subsequently, a process similar to the process described above may be performed between the plurality of second semiconductor chips 200. Accordingly, the plurality of bonding pads 300 may be formed by coupling the plurality of first preliminary bonding pads 300a and the plurality of corresponding second preliminary bonding pads 300b to each other and the bonding insulating layer 310 may be formed by coupling the first preliminary bonding insulating layer 310a and the second preliminary bonding insulating layer 310b to each other. The plurality of second semiconductor chips 200 may be sequentially attached to the lowermost second semiconductor chip 200L by the plurality of bonding pads 300 and the bonding insulating layers 310.

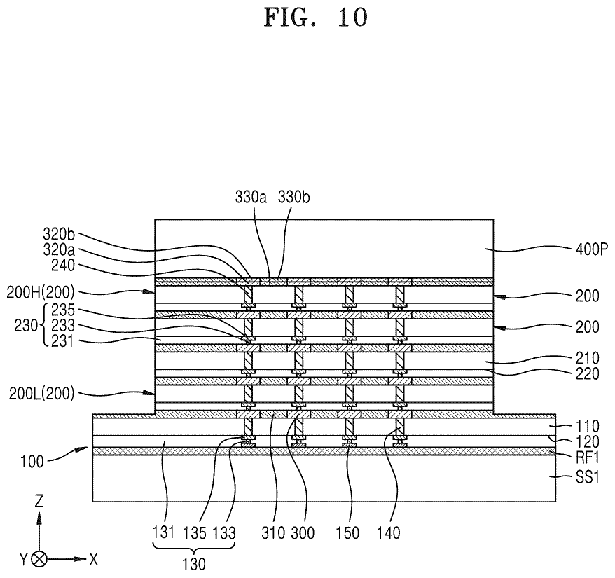

Referring to FIG. 10, a second preliminary support bonding pad 320b and a second preliminary support bonding insulating layer 330b may be formed on the lower surface of a preliminary lower dummy support substrate 400P, and then the preliminary lower dummy support substrate 400P may be placed on the uppermost second semiconductor chip 200H. The preliminary lower dummy support substrate 400P may be placed on the uppermost second semiconductor chip 200H by using an edge of the uppermost second semiconductor chip 200H as an alignment key.

Referring to FIG. 11, a process similar to the process described above with reference to FIG. 9 may be performed between the uppermost second semiconductor chip 200H and the preliminary lower dummy support substrate 400P. The plurality of support bonding pads 320 may be formed by coupling the plurality of first preliminary support bonding pads 320a and the plurality of corresponding second preliminary support bonding pads 320b to each other and the support bonding insulating layer 330 may be formed by coupling the first preliminary support bonding insulating layer 330a and the second preliminary support bonding insulating layer 330b to each other. The lower dummy support substrate 400 may be attached to the uppermost second semiconductor chip 200H by the plurality of support bonding pads 320 and the support bonding insulating layer 330.

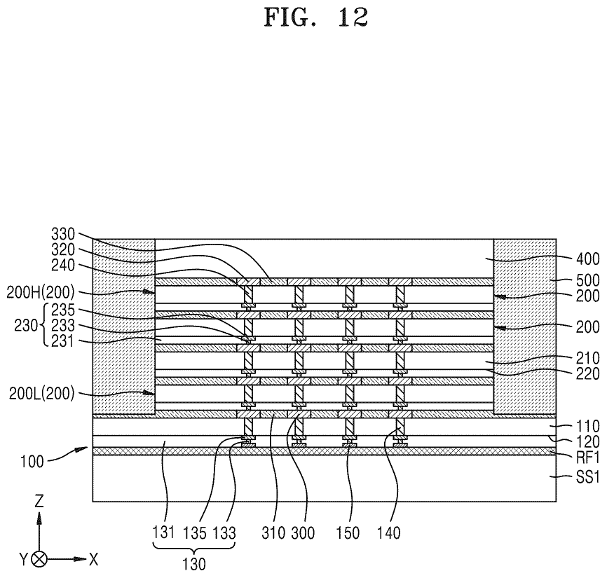

Referring to FIG. 12, a package molding layer 500 may be formed on the result of FIG. 11. In embodiments, the package molding layer 500 may cover the upper surface of the preliminary lower dummy support substrate 400P of FIG. 11. Subsequently, a process of grinding the package molding layer 500 formed on the upper surface of the preliminary lower dummy support substrate 400P of FIG. 11 and an upper portion of the preliminary lower dummy support substrate 400P may be further performed. The grinding process may be performed so that the vertical height of the package molding layer 500 is about 200 micrometers to about 500 micrometers. However, when the vertical height of the preliminary lower dummy support substrate 400P is about 200 micrometers to about 500 micrometers, the grinding process may be omitted. In this case, the package molding layer 500 may cover the upper surface of the preliminary lower dummy support substrate 400P.

Accordingly, the package molding layer 500, which covers the upper surface of the first semiconductor chip 100 and be adjacent to and surrounds the side surfaces of the plurality of second semiconductor chips 200 and the lower dummy support substrate 400, may be formed on the first semiconductor chip 100. After the package molding layer 500 is formed, the first support substrate SS1, to which the first release film RF1 is attached, may be separated from the first semiconductor chip 100.

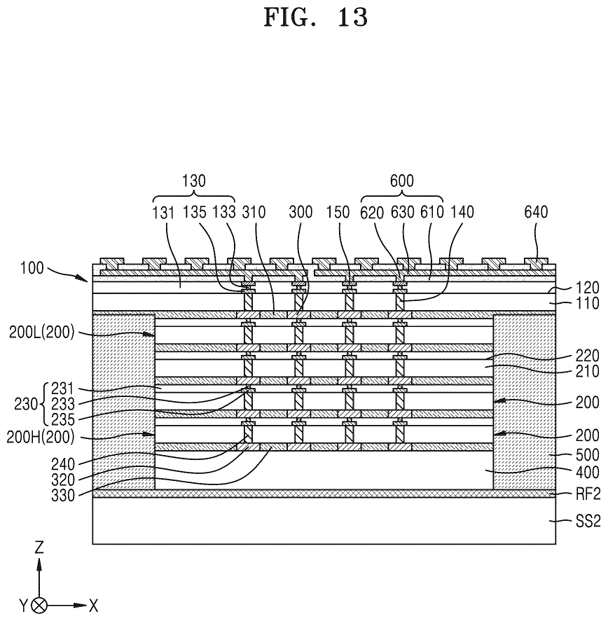

Referring to FIG. 13, after the result of FIG. 12 is turned over, the flipped result of FIG. 12 may be attached to a second support substrate SS2 to which a second release film RF2 is attached. Depending on the process, the second release film RF2 may be omitted. The second release film RF2 may be formed on the upper surface of the second support substrate SS2, and the lower dummy support substrate 400 and the package molding layer 500 may be attached to the upper surface of the second release film RF2.

Subsequently, a base redistribution layer 600 may be formed on the first wiring structure 130 of the first semiconductor chip 100. The base redistribution layer 600 may include a package redistribution insulating layer 610, a plurality of package redistribution vias 620, and a plurality of package redistribution line patterns 630. At least some of the plurality of package redistribution vias 620 or at least some of the plurality of package redistribution line patterns 630 may be in contact with the plurality of chip pads 150. A package redistribution line pattern 630, which is disposed on the upper surface of the base redistribution layer 600, among the plurality of package redistribution line patterns 630 may form a package pad 640.

In embodiments, the plurality of package redistribution vias 620 may each have a tapered shape extending from the bottom to the top with an increasing horizontal width.

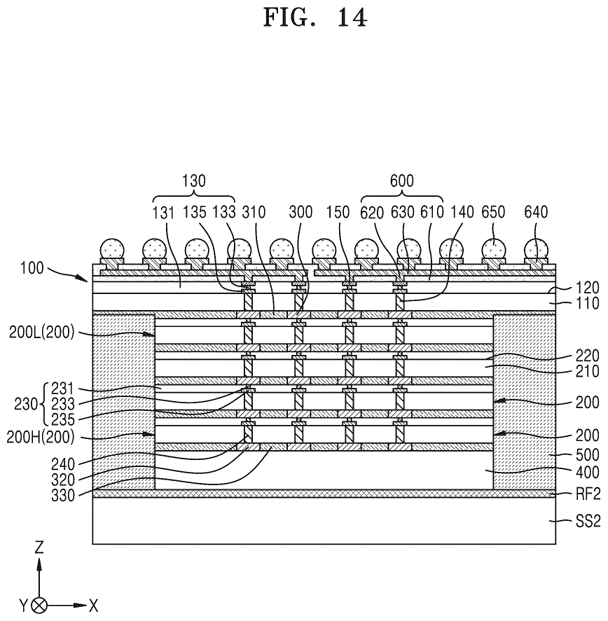

Referring to FIG. 14, a plurality of package connection terminals 650 may be respectively attached to a plurality of package pads 640. For example, each of the package connection terminals 650 may include a solder ball or a bump. Depending on the process, the base redistribution layer 600 may be omitted. In this case, the plurality of package connection terminals 650 may be attached to the plurality of chip pads 150.

Hereinafter, a method of manufacturing the semiconductor package 10 shown in FIG. 1 is described in detail with reference to FIGS. 15A and 15B.

Referring to FIG. 15A, the second support substrate SS2, to which the second release film RF2 is attached, may be separated from the result of FIG. 14, and the result, from which the second support substrate SS2 and the second release film RF2 attached thereto have been removed, may be turned over.

Subsequently, the package molding layer 500 may be partially removed to form a package molding cut MC. The package molding layer 500 may be partially removed by a sawing process. A diamond or cemented carbide sawing blade may be used to perform the sawing process. The horizontal width of the sawing blade may be less than the horizontal width of the package molding layer 500 and the vertical height of the sawing blade may be less than the vertical height of the package molding layer 500.

After the sawing process is performed, the remaining package molding layer 500 may be adjacent to and surround the side walls of the plurality of second semiconductor chips 200 and the lower dummy support substrate 400 and may also cover the upper surface of the first semiconductor chip 100. A portion of the remaining package molding layer 500, which be adjacent to and surrounds the side walls of the plurality of second semiconductor chips 200 and the lower dummy support substrate 400, may form a side molding portion 500a and another portion of the remaining package molding layer 500, which covers the upper surface of the first semiconductor chip 100, may form a bottom molding portion 500b.

Referring to FIG. 15B, a cover layer 700 may be formed on the result of FIG. 15A. The cover layer 700 may fill the interior of the package molding cut MC. The cover layer 700 may include a side cover portion 700a filling the interior of the package molding cut MC and may also include a top cover portion 700b covering the upper surface of the lower dummy support substrate 400 and the upper surface of the package molding layer 500. In embodiments, the cover layer 700 may include an inorganic material, such as an oxide, but embodiments are not limited thereto. Any material may be included in the cover layer 700 as long as the material may fill a space between the lower dummy support substrate 400 and an upper dummy support substrate 800 to attach the upper dummy support substrate 800 to the lower dummy support substrate 400. For example, the cover layer 700 may be formed by spin-coating the above-described material constituting the cover layer 700 on the result of FIG. 15A. The method of forming the cover layer 700 is not limited to the spin coating, and various other methods may be used.

Subsequently, the upper dummy support substrate 800 may be attached to the resulting cover layer 700. The upper dummy support substrate 800 may include, for example, a semiconductor material, such as silicon (Si). The upper dummy support substrate 800 may include only the semiconductor material. For example, the upper dummy support substrate 800 may include a portion of a bare wafer.

In order to form individual semiconductor packages from the result to which the upper dummy support substrate 800 has been attached, a dicing process may be performed along scribe lanes.

Hereinafter, a method of manufacturing the semiconductor package 20 shown in FIG. 3 is described in detail with reference to FIGS. 16A and 16B.

Referring to FIG. 16A, the second support substrate SS2, to which the second release film RF2 is attached, may be separated from the result of FIG. 14, and the result, from which the second support substrate SS2 and the second release film RF2 attached thereto have been removed, may be turned over.

Subsequently, a cover layer 700 may be formed on the result from which the second support substrate SS2 and the second release film RF2 attached thereto have been removed. The cover layer 700 may cover the upper surface of the lower dummy support substrate 400 and the upper surface of the package molding layer 500. In embodiments, the cover layer 700 may include an inorganic material, such as an oxide, but embodiments are not limited thereto. Any material may be included in the cover layer 700 as long as the material may fill a space between the lower dummy support substrate 400 and an upper dummy support substrate 800 to attach the upper dummy support substrate 800 to the lower dummy support substrate 400. For example, the cover layer 700 may be formed by spin-coating the above-described material constituting the cover layer 700 on the upper surface of the lower dummy support substrate 400 and the upper surface of the package molding layer 500. The method of forming the cover layer 700 is not limited to the spin coating, and various other methods may be used.

Subsequently, the upper dummy support substrate 800 may be attached to the resulting cover layer 700. The upper dummy support substrate 800 may include, for example, a semiconductor material, such as silicon (Si). The upper dummy support substrate 800 may include only the semiconductor material. For example, the upper dummy support substrate 800 may include a portion of a bare wafer.

Referring to FIG. 16B, a package molding cut MC may be formed by partially removing the package molding layer 500, the cover layer 700, and the upper dummy support substrate 800 from the result of FIG. 16A.

The package molding layer 500, the cover layer 700, and the upper dummy support substrate 800 may be partially removed by a sawing process. A diamond or cemented carbide sawing blade may be used to perform the sawing process. The horizontal width of the sawing blade may be less than the horizontal width of the package molding layer 500 and the vertical height of the sawing blade may be less than the vertical height of the package molding layer 500.

After the sawing process is performed, the remaining package molding layer 500 may be adjacent to and surround the side walls of the plurality of second semiconductor chips 200 and the lower dummy support substrate 400 and may also cover the upper surface of the first semiconductor chip 100. A portion of the remaining package molding layer 500, which be adjacent to and surrounds the side walls of the plurality of second semiconductor chips 200 and the lower dummy support substrate 400, may form a side molding portion 500a and another portion of the remaining package molding layer 500, which covers the upper surface of the first semiconductor chip 100, may form a bottom molding portion 500b.

In order to form individual semiconductor packages from the result to which the upper dummy support substrate 800 has been attached, a dicing process may be performed along scribe lanes.

Hereinafter, a method of manufacturing the semiconductor package 30 shown in FIG. 5 is described in detail with reference to FIGS. 17A and 17B.

The second support substrate SS2, to which the second release film RF2 is attached, may be separated from the result of FIG. 14, and the result, from which the second support substrate SS2 and the second release film RF2 attached thereto have been removed, may be turned over.

Subsequently, the package molding layer 500 may be partially removed to form a plurality of package molding cuts MC. The package molding layer 500 may be partially removed by a sawing process. A diamond or cemented carbide sawing blade may be used to perform the sawing process. The horizontal width of the sawing blade may be less than the horizontal width of the package molding layer 500 and the vertical height of the sawing blade may be less than the vertical height of the package molding layer 500. The sum of the horizontal widths of the plurality of package molding cuts MC may be less than the horizontal width of the package molding layer 500 and the vertical height of each of the plurality of package molding cuts MC may be less than the vertical height of the package molding layer 500.

After the sawing process is performed, the remaining package molding layer 500 may be adjacent to and surround the side walls of the plurality of second semiconductor chips 200 and the lower dummy support substrate 400 and may also cover the upper surface of the first semiconductor chip 100. A portion of the remaining package molding layer 500, which covers the upper surface of the first semiconductor chip 100, may form a bottom molding portion 500b and other portions of the remaining package molding layer 500, which extend from edges of the bottom molding portion 500b in the vertical direction Z, may form a plurality of side molding portions 500a. The plurality of side molding portions 500a may be spaced apart from each other with the package molding cut MC therebetween. The side molding portions 500a may be exposed through the side walls of the package molding cuts MC and the bottom molding portion 500b may be exposed through the bottoms of the package molding cut MC.

Referring to FIG. 17B, a cover layer 700 may be formed on the result of FIG. 17A. The cover layer 700 may fill the interior of the plurality of package molding cuts MC. The cover layer 700 may include a plurality of side cover portions 700a filling the interior of the plurality of package molding cuts MC and may also include a top cover portion 700b covering the upper surface of the lower dummy support substrate 400 and the upper surface of the package molding layer 500. In embodiments, the cover layer 700 may include an inorganic material, such as an oxide, but embodiments are not limited thereto. Any material may be included in the cover layer 700 as long as the material may fill a space between the lower dummy support substrate 400 and an upper dummy support substrate 800 to attach the upper dummy support substrate 800 to the lower dummy support substrate 400. For example, the cover layer 700 may be formed by spin-coating the above-described material constituting the cover layer 700 on the result of FIG. 17A. The method of forming the cover layer 700 is not limited to the spin coating, and various other methods may be used.

Subsequently, the upper dummy support substrate 800 may be attached to the resulting cover layer 700. The upper dummy support substrate 800 may include, for example, a semiconductor material, such as silicon (Si). The upper dummy support substrate 800 may include, for example, only the semiconductor material. For example, the upper dummy support substrate 800 may include a portion of a bare wafer.

In order to form individual semiconductor packages from the result to which the upper dummy support substrate 800 has been attached, a dicing process may be performed along scribe lanes.

During the process of manufacturing the semiconductor package according to embodiments, the package molding layer 500 may be partially removed by the sawing process to form the package molding cut MC. The sawing process may prevent or reduce excessive thermal expansion of the package molding layer 500 and thus suppress the occurrence of warpage of the package molding layer 500.

Also, since the first semiconductor chip 100, the plurality of second semiconductor chips 200, and the lower dummy support substrate 400 are connected to each other through the hybrid bonding, the surface roughness of the first semiconductor chip 100 and the plurality of second semiconductor chips 200 may be accumulated up to the upper surface of the lower dummy support substrate 400. According to embodiments, the cover layer 700 is formed between the lower dummy support substrate 400 and the upper dummy support substrate 800. Accordingly, the surface roughness of the lower dummy support substrate 400 is compensated for by the cover layer 700, and thus, the upper dummy support substrate 800 may be properly connected to the cover layer 700. Consequently, it is possible to improve the structural stability of the semiconductor package.

While the inventive concept has been particularly shown and described with reference to embodiments thereof, it will be understood that various changes in form and details may be made therein without departing from the spirit and scope of the following claims.

What is claimed is:

1. A semiconductor package comprising:
a first semiconductor chip comprising a first semiconductor substrate having an active surface and an inactive surface opposite to each other and a plurality of first through-electrodes penetrating the first semiconductor chip;
a plurality of second semiconductor chips each comprising a second semiconductor substrate having an active surface and an inactive surface opposite to each other and a plurality of second through-electrodes penetrating the plurality of second semiconductor chips, respectively, the plurality of second semiconductor chips being on the first semiconductor chip, the active surfaces of the plurality of second semiconductor substrates facing the inactive surface of the first semiconductor substrate, and the plurality of second semiconductor chips comprising a lowermost second semiconductor chip and an uppermost second semiconductor chip;
a plurality of bonding pads between the first semiconductor chip and the lowermost second semiconductor chip and between the second semiconductor chips among the plurality of second semiconductor chips adjacent to each other, the plurality of bonding pads electrically connecting the plurality of first through-electrodes and the plurality of second through-electrodes to each other;
a plurality of bonding insulating layers respectively between the first semiconductor chip and the lowermost second semiconductor chip and between the second semiconductor chips among the plurality of second semiconductor chips adjacent to each other, the plurality of bonding insulating layers being adjacent to the plurality of bonding pads; and
a package molding layer comprising a bottom molding portion on a portion of an upper surface of the first semiconductor chip exposed by the lowermost second semiconductor chip, and a side molding portion on side walls of the plurality of second semiconductor chips,
wherein the side molding portion included in the package molding layer extends in a vertical direction from an edge of an upper surface of the bottom molding portion included in the package molding layer.

2. The semiconductor package of claim 1, wherein the side molding portion included in the package molding layer is on a portion of the upper surface of the bottom molding portion included in the package molding layer.

3. The semiconductor package of claim 1, wherein a width of the side molding portion included in the package molding layer is less than a width of the bottom molding portion included in the package molding layer in a horizontal direction.

4. The semiconductor package of claim 1, further comprising a lower dummy support substrate on the uppermost second semiconductor chip.

5. The semiconductor package of claim 1, further comprising a cover layer on the package molding layer.

6. The semiconductor package of claim 5, wherein the package molding layer comprises a package molding cut,
wherein the side molding portion of the package molding layer contacts the cover layer through a side wall of the package molding cut, and
wherein the bottom molding portion of the package molding layer contacts the cover layer through a bottom of the package molding cut.

7. The semiconductor package of claim 5, wherein the package molding layer comprises a package molding cut,
wherein the side molding portion of the package molding layer is exposed through a side wall of the package molding cut, and
wherein the bottom molding portion of the package molding layer is exposed through a bottom of the package molding cut.

8. The semiconductor package of claim 5, wherein the package molding layer comprises a plurality of package molding cuts,
wherein the side molding portion included in the package molding layer comprises a plurality of side molding portions,
wherein the plurality of side molding portions contact the cover layer through side walls of the plurality of package molding cuts, respectively, and
wherein the bottom molding portion included in the package molding layer contacts the cover layer through bottoms of the plurality of package molding cuts.

9. The semiconductor package of claim 5, further comprising an upper dummy support substrate on the cover layer,
wherein a vertical height of the upper dummy support substrate is greater than a sum of a vertical height of the first semiconductor chip and a vertical height of one of the plurality of second semiconductor chips.

10. The semiconductor package of claim 5, wherein a height of a portion of the cover layer, which is on an upper surface of the side molding portion included in the package molding layer, is less than a height of the first semiconductor chip in a vertical direction.

11. A semiconductor package comprising:
a first semiconductor chip comprising a first semiconductor substrate having an active surface and an inactive surface opposite to each other and a plurality of first through-electrodes penetrating the first semiconductor chip;
a plurality of second semiconductor chips each comprising a second semiconductor substrate having an active surface and an inactive surface opposite to each other and a plurality of second through-electrodes penetrating the plurality of second semiconductor chips, respectively, the plurality of second semiconductor chips being on the first semiconductor chip, the active surfaces of the plurality of second semiconductor substrates facing the inactive surface of the first semiconductor substrate, and the plurality of second semiconductor chips comprising a lowermost second semiconductor chip and an uppermost second semiconductor chip;
a plurality of bonding pads between the first semiconductor chip and the lowermost second semiconductor chip and between the second semiconductor chips among the plurality of second semiconductor chips adjacent to each other, the plurality of bonding pads electrically connecting the plurality of first through-electrodes and the plurality of second through-electrodes to each other;
a plurality of bonding insulating layers respectively between the first semiconductor chip and the lowermost second semiconductor chip and between the second semiconductor chips among the plurality of second semiconductor chips adjacent to each other, the plurality of bonding insulating layers being adjacent to the plurality of bonding pads;
a lower dummy support substrate on the uppermost second semiconductor chip;
a cover layer comprising a top cover portion on an upper surface of the lower dummy support substrate and a side cover portion extending from the top cover portion and horizontally spaced apart from the lower dummy support substrate and the plurality of second semiconductor chips; and
a package molding layer on a portion of an upper surface of the first semiconductor chip exposed by the lowermost second semiconductor chip, and being between the first semiconductor chip and the cover layer.

12. The semiconductor package of claim 11, wherein the package molding layer and the cover layer comprise different materials from each other.

13. The semiconductor package of claim 11, wherein the package molding layer comprises a bottom molding portion on the portion of the upper surface of the first semiconductor chip, exposed by the lowermost second semiconductor chip, and a side molding portion that extends from an upper surface of the bottom molding portion in a vertical direction and is in contact with the lower dummy support substrate and the plurality of second semiconductor chips.

14. The semiconductor package of claim 13, wherein the side cover portion included in the cover layer is on the upper surface included in the bottom molding portion of the package molding layer, and
wherein the top cover portion of the cover layer is on an upper surface of the side molding portion included in the package molding layer.

15. The semiconductor package of claim 12, wherein a height of the top cover portion included in the cover layer is less than a height of the first semiconductor chip in a vertical direction.

16. The semiconductor package of claim 12, further comprising an upper dummy support substrate on the cover layer,
wherein a height of the upper dummy support substrate is greater than a sum of a height of the first semiconductor chip and a height of any one of the plurality of second semiconductor chips in a vertical direction.

17. A semiconductor package comprising:
a first semiconductor chip comprising a first semiconductor substrate having an active surface and an inactive surface opposite to each other and a plurality of first through-electrodes penetrating the first semiconductor chip;
a plurality of second semiconductor chips each comprising a second semiconductor substrate having an active surface and an inactive surface opposite to each other and a plurality of second through-electrodes penetrating the plurality of second semiconductor chips, respectively, the plurality of second semiconductor chips being on the first semiconductor chip, the active surfaces of the plurality of second semiconductor substrates facing the inactive surface of the first semiconductor substrate, and the plurality of second semiconductor chips comprising a lowermost second semiconductor chip and an uppermost second semiconductor chip;
a plurality of bonding pads between the first semiconductor chip and the lowermost second semiconductor chip and between the second semiconductor chips among the plurality of second semiconductor chips adjacent to each other, the plurality of bonding pads electrically connecting the plurality of first through-electrodes and the plurality of second through-electrodes to each other;
a plurality of bonding insulating layers respectively between the first semiconductor chip and the lowermost second semiconductor chip and between the second semiconductor chips among the plurality of second semiconductor chips adjacent to each other, the plurality of bonding insulating layers being adjacent to the plurality of bonding pads;
a package molding layer comprising a bottom molding portion on a portion of an upper surface of the first semiconductor chip, exposed by the lowermost second semiconductor chip, and a side molding portion on side walls of the plurality of second semiconductor chips;
a lower dummy support substrate on the uppermost second semiconductor chip;
a cover layer on the lower dummy support substrate; and
an upper dummy support substrate on the cover layer,
wherein the side molding portion included in the package molding layer extends in a vertical direction from an edge of an upper surface of the bottom molding portion included in the package molding layer, and
a width of the side molding portion of the package molding layer is less than a width of the bottom molding portion of the package molding layer in a horizontal direction.

18. The semiconductor package of claim 17, wherein the package molding layer comprises a package molding cut,
wherein the cover layer extends and fills an interior of the package molding cut,
wherein the side molding portion included in the package molding layer contacts the cover layer through a side wall of the package molding cut, and
wherein the bottom molding portion included in the package molding layer contacts the cover layer through a bottom of the package molding cut.

19. The semiconductor package of claim 17, wherein the package molding layer comprises a package molding cut,
wherein the side molding portion included in the package molding layer is exposed through a side wall of the package molding cut, and
wherein the bottom molding portion of the package molding layer is exposed through a bottom of the package molding cut.

20. The semiconductor package of claim 17, wherein the package molding layer comprises a plurality of package molding cuts,
wherein the cover layer extends and fills interiors of the plurality of package molding cuts,
wherein the side molding portion included in the package molding layer comprises a plurality of side molding portions,
wherein the plurality of side molding portions contact the cover layer through side walls of the plurality of package molding cuts, respectively, and
wherein the bottom molding portion included in the package molding layer contacts the cover layer through bottoms of the plurality of package molding cuts.
